(19) United States
(12) Patent Application Publication
(10) Pub. No.: US 2026/0092962 A1
(43) Pub. Date: Apr. 2, 2026

(54) MULTIMODE SENSING SYSTEM FOR MEDIUM AND HIGH VOLTAGE CABLES AND EQUIPMENT

(71) Applicants: 3M Innovative Properties Company, St. Paul, MN (US); Connected Intelligence Systems Ltd., Netanya (IL)

(72) Inventors: Douglas B. Gundel, Cedar Park, TX (US); Johannes Fink, Bergheim (DE); David V. Mahoney, Austin, TX (US); Eyal Doron, Caesarea (IL); Uri Bar-Ziv, Zichron Yaakov (IL)

(21) Appl. No.: 19/110,678

(22) PCT Filed: Dec. 27, 2022
(86) PCT No.: PCT/US2022/082429

§ 371 Date: Mar. 11, 2025

Related U.S. Application Data
(60) Provisional application No. 63/375,970, filed on Sep. 16, 2022.

(51) Int. Cl. G01R 31/08; G01R 31/11; H02J 50/00

(52) U.S. Cl. CPC G01R 31/085; G01R 31/088; G01R 31/11; H02J 50/001

(57) ABSTRACT

An example system is configured to monitor one or more conditions of an electric powerline. The system includes a node operatively coupled to an electrical cable of the one or more electrical cables and communicatively coupled to a central computing system. The node comprises a sensor configured to acquire a first sensor data and to acquire a second sensor data different from the first sensor data, and the node is configured to deliver the first sensor data and the second sensor data, to the central computing system.

This application claims priority to U.S. Provisional Application number 63/375,970, filed Sep. 16, 2022, which is incorporated herein by reference in its entirety.

### TECHNICAL FIELD

The present disclosure relates to the field of electrical equipment, including power cables and accessories, for power utilities and industrial and commercial sites.

### BACKGROUND

Electrical power grids include numerous components that operate in diverse locations and conditions, such as above ground, underground, cold weather climates, and/or hot weather climates. When a power grid suffers a failure, it can be difficult to determine the cause of the failure. Sensor systems for power networks, especially underground power networks, are increasingly becoming employed to detect grid anomalies (such as faults or precursors of faults) so that an operator can react more quickly, effectively, and safely to maintain service or return the system to service. Examples of sensor systems include faulted-circuit indicators, reverse-flow monitors, and power-quality monitors. Commonly assigned U.S. Pat. No. 9,961,418, incorporated by reference herein in its entirety, describes an underground power-network-monitoring system that communicates with a central system. Commonly assigned International Patent Application No. PCT/US2020/067683, incorporated by reference herein in its entirety, describes techniques for capacitively coupling monitoring devices to an electrical power network. Commonly assigned International Patent Application No. PCT/US2022/072901, incorporated by reference herein in its entirety, describes multi-functional, high-density electrical-grid monitoring.

### SUMMARY

In general, the present disclosure describes systems and techniques for monitoring an electric power grid, e.g., for evaluating a condition of power cables and/or other electrical equipment. The systems described herein include a plurality of distributed monitoring devices, or “nodes.” For instance, a monitoring system may include one or more nodes configured to acquire a first sensor data and a second sensor data different from the first sensor data and to communicate with a central monitoring system to deliver the first and second sensor data to the central monitoring system. In some examples, the first sensor data and the second sensor data may be data acquired at different times, and in some examples, the first and second sensor data may be different data types taken at the same or different times. For example, the first sensor data may be a first sensor data type, e.g., a frequency domain reflectometry, a time domain reflectometry, a partial discharge, a voltage, a current, a temperature, or any data suitable for monitoring a power cable, and the second sensor data may be a second sensor data type which may be a different one of, for example, a frequency domain reflectometry, a time domain reflectometry, a partial discharge, a voltage, a current, a temperature, or any data suitable for monitoring a power cable.

Acquiring first and second sensor data, e.g., acquired at the same time and of different types or acquired at different times and of the same or different type, enables using the first and second sensor data in combination to improve the accuracy of determinations regarding the condition of power cable and/or power grid, improve locating and identifying defects on the power cable and/or power grid, assess and report any damage and/or damage severity to the cable and/or power grid, determinations regarding future probability and/or timing of failure of the power cable and/or power grid.

In one example, this disclosure describes a system configured to: monitor one or more conditions of an electric powerline includes a node operatively coupled to an electrical cable of the one or more electrical cables and communicatively coupled to a central computing system, wherein the node comprises: a sensor configured to acquire a first sensor data and to acquire a second sensor data different from the first sensor data. wherein the node is configured to deliver the first sensor data and the second sensor data to the central computing system.

In another example, this disclosure describes a node including: a sensor configured to acquire a first sensor data and to acquire a second sensor data different from the first sensor data, wherein the node operatively coupled to an electrical cable of an electric powerline and communicatively coupled to a central computing system, wherein the node is configured to deliver the first sensor data and the second sensor data to the central computing system.

In another example, this disclosure describes a method including: receiving, from a node operatively coupled to an electrical cable of an electric powerline, a first sensor data; receiving, from the node, a second sensor data different from the first sensor data; determining, based on the first sensor data, at least one of a health of a component of the electric powerline, a failure condition of a device coupled to the power line, a pre-failure condition of a device coupled to the power line, one or more environmental conditions at the node, a state or operability of an electrical grid comprising the electric powerline, a presence of a defect in the electric powerline, or a location of a defect in the electric powerline; and increasing, based on the second sensor data, an accuracy of the determination.

The details of one or more examples are set forth in the accompanying drawings and the description below. Other features, objects, and advantages will be apparent from the description, drawings, and claims.,

### BRIEF DESCRIPTION OF THE DRAWINGS

FIGS. 1A and 1B are conceptual diagrams illustrating respective example power-cable constructions,

FIG. 2 is a conceptual block diagram of an example electrical power network including primary and secondary monitoring nodes.

FIG. 3 is a conceptual block diagram of an example electrical power grid with primary and secondary monitoring nodes positioned at electrical cables and accessories.

FIG. 4 is a schematic view of one example configuration for a monitoring node, including a pad-mounted data communication system.

FIGS. 5 and 6 are schematic diagrams of example techniques for coupling primary and/or secondary monitoring nodes to power cables, enabling powerline communication.

FIG. 7A is a block diagram illustrating an example configuration for a monitoring node electrically coupled to a power-delivery system via a removable T-body connector.

FIG. 7B is a block diagram illustrating an example configuration for a monitoring node electrically coupled to a power-delivery system via a removable elbow connector.

FIG. 7C is a block diagram illustrating an example configuration for a monitoring node, in which the coupling mechanism and the electronics are located in a plug with external connections optionally routed through an end cap. Removal of the end cap exposes a test point to enable local determination of whether the powerline is currently energized.

FIG. 7D is a block diagram illustrating an example configuration for a monitoring node, in which the node coupling is located in the plug and the electronics are housed in an extension module that is removably or permanently connected to the plug. Connection to other devices and sensors can optionally be routed through the end cap.

FIG. 7E is a block diagram illustrating an example configuration for a monitoring node, in which the primary node coupling is located in the plug and the electronics are housed in the end cap with external connections.

FIG. 7F is a block diagram illustrating an example configuration for a monitoring node, in which the coupling is located in the plug, the connections are housed in the end cap, and the electronics are housed in a physically distinct module.

FIG. 8A is a diagram illustrating an example of a secondary monitoring node coupled to a single phase of an electrical cable.

FIG. 8B is a diagram illustrating an example arrangement in which multiple secondary nodes are connected locally on a multiphase electrical cable. Data can be shared between the phases for timing or for communication redundancy. If more than one phase is coupled to the same electronics, the communication can be sent on two or more lines for redundancy, e.g., if a channel is disrupted, or the signal can be distributed on two or more lines.

FIG. 8C is a diagram illustrating another example polyphase deployment of secondary nodes in which processing circuitry for multiple secondary nodes may be located within just one of the secondary nodes, with a data connection or other direct coupling between each of the secondary nodes.

FIG. 8D is a diagram illustrating another polyphase deployment of secondary nodes in which processing circuitry for multiple secondary nodes is housed within a distinct module communicatively coupled to each phase of the cable.

FIG. 9 is a block diagram illustrating an example configuration for a monitoring node electrically coupled to a power-delivery system via a removable T-body connector and an insulating plug.

FIG. 10 illustrates an alternative physical interface to the insulating plug. The capacitive element or elements can be embedded within the termination or within the equipment.

FIG. 11 is a block diagram illustrating an example configuration for a monitoring node electrically coupled to a power-delivery system via a removable T-body connector.

FIG. 12 is a block diagram illustrating an example configuration for a monitoring node electrically coupled to a power-delivery system via a removable elbow connector.

FIG. 13 is a block diagram illustrating an example configuration for a monitoring node electrically coupled to a power-delivery system via a live front termination.

FIG. 14 illustrates a representative deployment of the device at cable termination locations at or near the substation or in pad mounted equipment. The cable system and adjacent equipment can be monitored.

FIG. 15 illustrates another representative deployment of the device where the device can also introduce a signal on command the interacts with a defect in the cable and that interaction allows the defect to be located with a handheld or other locating device.

FIG. 16 is a flowchart illustrating example techniques for monitoring an electric power network, in accordance with this disclosure.

It is to be understood that the embodiments may be utilized, and structural changes may be made without departing from the scope of the invention. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Examples of the present disclosure include devices, techniques, and systems for sensing, communicating, and characterizing a condition of an electrical grid. As such, the example devices described herein include multifunctional (sensing, communication, and characterization) devices. In this aspect, example devices may include a coupling layer that can provide a sensing layer that senses native signals and intentional (e.g., injected) signals. Moreover, the coupling layer may also provide for communication (e.g., signal injection, signal reception) and channel characterization,

Medium and high voltage (MV, HV) power distribution systems may suffer failure due to the interaction of the electrical stress with pre-existing or emerging structural defects in cables, cable accessories, and other equipment. These failures may be unexpected and may result in worker and public safety risks, loss of production and revenue, liability, reduced reliability metrics, and cascading failures due to overload of the remaining system. Avoidance of failure is often desired, but if the failure location can be identified quickly then the operator can repair it in a planned process thereby minimizing some of the negative impacts. An on-line continuous monitoring of the distribution system to detect and locate failure locations and to detect and locate pre-fault defects (pre-existing and new structural defects that are at risk of imminent failure) may be advantageous. Widespread deployment of such a system may provide a reduction in the time required to repair a cable system failure (fault) and allow the operator to address and correct equipment issues and avoid failures altogether.

In accordance with aspects of this disclosure, a grid monitoring system and components may be configured to monitor and report grid conditions including asset health, environmental conditions, grid state, fault detection and location, and can control field devices. The monitoring system may be one or more measurement devices that are located at specific parts of a single distributed power distribution grid. The devices may cooperate to identify a condition of the power distribution grid (e.g., defects types, locations, and/or severity, grid and/or component health, location, performance and/or capability of the grid and/or components of the grid) from two or more measurements, e.g., two or more measurement types, the same or different measurement types at different times or during different time periods, from the same or different sites (e.g., locations of the power distribution grid), and more accurately assess the location or other aspects of the condition (e.g., severity, type, etc.). These monitoring devices and/or nodes are coupled to the power line and may perform more than one function on the live power cable during online monitoring: voltage sensing, zero crossing, power harvesting, reflectometry (time or frequency domain), partial discharge sensing, cable locating, defect locating, voltage and current waveform sampling, power quality measurements, power line communications and other functions. The functions can share the same point of coupling (e.g., a capacitor or capacitive coupling) and the sharing may be enabled by time-sharing of the coupling device. Some functions may not be realized through the same coupling and may include temperature measurement, current measurement, or any suitable power distribution grid measurement. In addition, the combined results of the one or more functions may be used together to provide higher accuracy data about the condition of the power distribution grid and/or cable system, and/or attached equipment (e.g., greater certainty and/or accuracy in assessing a defect location, type, severity, health of the grid, or the like) or assess and report the condition of the severity of damage, an amount of a risk of failure of the power distribution grid, cabling, and/or components of the grid, or time to failure (e.g., including a confidence interval), and/or confirm the condition and monitor its progression over time.

Some example techniques herein include coupling a sensing-and-communicating (“monitoring”) system onto a medium-voltage (MV) or high-voltage (HV) electrical-power-cable system. In particular, the monitoring systems described herein include a plurality of distributed monitoring devices, or “nodes.” One or more of the plurality of nodes may be configured to acquire a plurality of data types associated with the electrical-power-cable system. For examples, a node may be configured to acquire a first sensor data, or data set, of a first type, e.g., a frequency domain reflectometry, a time domain reflectometry, a partial discharge, a voltage, a current, a temperature, or any data suitable for monitoring a power cable. The node may be configured to acquire a second sensor data different from the first sensor data in time, e.g., a second sensor data set of the same type at a second time period, or the node may be configured to acquire a second sensor data different from the first sensor data in data type.

In some examples, a monitoring system may be retrofitted onto an existing MV or HV cable system, rather than incorporating a monitoring system within a cable system at the time of manufacture of the cable system. In some such retrofit examples, the techniques of this disclosure include coupling the systems without compromising the integrity of the cables, e.g., by cutting the cables or penetrating a radial layer of the cables (e.g., a cable jacket). For instance, some example techniques herein include capacitively coupling a partial-discharge (PD) detection system to a cable shield of a power cable. Additional and/or alternative example techniques herein include specialized removable connector devices to removably couple the secondary monitoring nodes to the power network.

Acquiring first and second sensor data, e.g., acquired at the same time and of different types or acquired at different times and of the same type or different types, enables using the first and second sensor data in combination to improve the accuracy of determinations regarding the condition of power cable and/or power grid, improve locating and identifying defects on the power cable and/or power grid, assess and report any damage and/or damage severity to the cable and/or power grid, determinations regarding future probability and/or timing of failure of the power cable and/or power grid. Distributing the monitoring devices may enable a substantially dense node-coverage of a power grid, e.g., enabling precise determinations of the locations of electrical faults or other anomalies,

In some examples, the plurality of nodes may include at least one “primary” monitoring node configured to communicate directly with a central monitoring system and at least one “secondary” monitoring node. In general, the secondary nodes described herein may be less technically complex than the primary nodes. This lower complexity, and accordingly, lower per-unit cost, facilitates a higher density of coverage of the power-cable system with a network of monitoring nodes. For instance, the primary nodes may include more complex processing and/or communication capabilities, e.g., configured to communicate monitoring data directly to a central computing system. By contrast, the secondary nodes may include more-limited data-processing functionality, and may be configured to communicate only to other monitoring nodes within the monitoring system. In some examples, the secondary monitoring nodes are further configured to communicate only via the powerline-communication techniques detailed herein.

The example devices and coupling techniques described herein enable the devices to communicate information, such as PD information, faulted-circuit indicator (FCI) information, electrical-current information, temperature information, or other information pertinent to the monitoring and maintenance of the electrical power network. Each coupling layer can be connected to a signal wire that can convey the detected or injected signal to or from a source, detector, processor, or other device. In some embodiments, a protective cover or wrapping can also be utilized to cover or protect the coupling layer and/or signal wire connection.

In accordance with aspects of this disclosure, for distributed networks on an electrical-power grid, example devices are configured to interface with an electrical-power cable with little-to-no modification or other alteration of the power cable, thereby reducing the potential for cable damage. Example systems herein are configured to use these example devices and coupling techniques to communicate along the powerline via a powerline-communication technique. In some examples, the devices may be retrofittable to an existing powerline. Alternatively, the techniques herein may be applied to example devices that are coupled to (e.g., integrated) with a newly installed powerline.

The multifunctional devices described herein can be integrated with various critical monitoring functionalities to support a grid operator in maintaining grid service or returning the grid to service when grid service is unavailable. For example, an FCI can include electrical-current sensing, hardware for processing FCI information, fault logic, communication, and power (e.g., potentially through inductive power-harvesting from the powerline). These systems and devices can be readily packaged in a (secondary) retrofittable node that has communication only along the powerline (e.g., communication only to other nodes in the network). Other supported functionalities can include power-quality monitoring, PD monitoring, discrete-temperature monitoring, fault location, time-domain or frequency-domain reflectometry, incipient fault detection, and other functions. In some examples, these other functions also can be supported by a retrofittable coupling mechanism to reduce the cost per device and complexity of deployment. For enabling communication, in accordance with techniques of this disclosure, the retrofittable coupling system can support communication to a primary, centrally connected node from a secondary, satellite node, or from the satellite node to another secondary node.

Powerlines may transmit electrical power from a power source (e.g., a power plant) to a power consumer, such as a business or home. Powerlines may be underground, underwater, or suspended overhead (e.g., from wooden poles, metal structures, etc.). Powerlines may be used for electrical-power transmission at relatively high voltages (e.g., compared to electrical cables utilized within a home, which may transmit electrical power between approximately 12 volts and approximately 240 volts depending on application and geographic region). For example, powerlines may transmit electrical power above approximately 600 volts (e.g., between approximately 600 volts and approximately 1,000 volts). However, it should be understood that powerlines may transmit electrical power over any voltage and/or frequency range. For example, powerlines may transmit electrical power within different voltage ranges. In some examples, a first type of powerline may transmit voltages of more than approximately 1,000 volts, such as for distributing power between a residential or small commercial customer and a power source (e.g., power utility). As another example, a second type of powerline may transmit voltages between approximately 1 kV and approximately 69 k V, such as for distributing power to urban and rural communities. A third type of powerline may transmit voltages greater than approximately 69 k V, such as for sub-transmission and transmission of bulk quantities of electric power and connection to very large consumers.

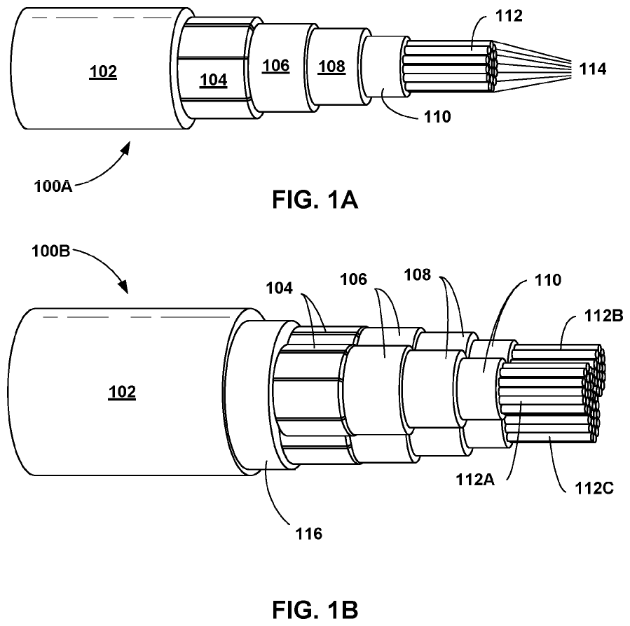

In some examples, powerlines may include electrical cables and one or more electrical cable accessories. For example, FIG. 1A and 1B depict two example electrical-power cables 100A and 100B (collectively, “cables 100,” or, in the alternative, “cable 100”), respectively. Power cable 100A is an example of a “single phase” MV cable, e.g., having only a single central conductor 112. Power cable 100A includes jacket or oversheath 102, metal sheath or cable shield 104, insulation screen 106, insulation 108, conductor screen 110, and central conductor 112. Power cable 100B is an example of a three-phase extruded medium-voltage (MV) cable, e.g., having three central conductors 112A-112C (collectively, “conductors 112,”or, in the alternative, “conductor 112”). Polyphase cables like cable 100B can carry more than one shielded-conductor 112 within a single jacket 102. Other examples of typical, but not depicted, cable layers include swellable or water-blocking materials that are placed within the conductor strands 114 (“strand fill”), or between various other layers of the cable 100 (“filler 116”).

Example cable accessories may include splices, separable connectors, terminations, and connectors, among others. In some examples, cable accessories may include cable splices configured to physically and conductively couple two or more cables 100. For example, a cable accessory can physically and conductively couple cable 100A or cable 100B to other electrical cables. In some examples, terminations may be configured to physically and conductively couple a cable 100 to additional electrical equipment, such as a transformer, switch gear, power substation, business, home, or other structure.

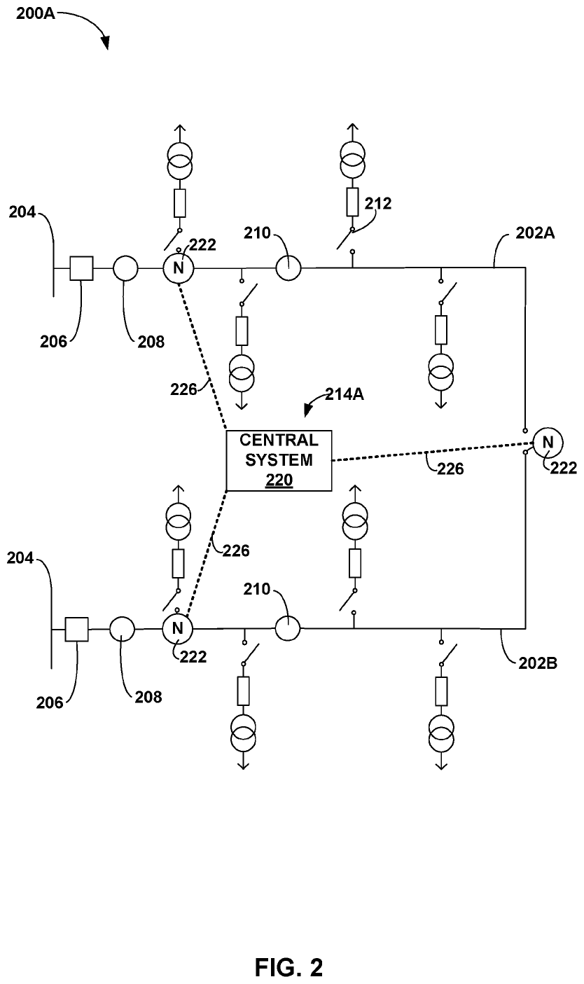

Electrical cables 100 and cable accessories can be assembled into an electrical power network, or in some specific examples thereof, an electrical power grid, to distribute electrical power to various consumers or other end-users. For instance, FIG. 2 is a conceptual block diagram depicting a first example electrical power network 200A, For instance, power network 200A includes at least two power-transmission lines or “feeder” lines 202A, 202B (collectively, “feeder lines 202”), which may be examples of power cables 100 of FIG. 1A and IB. Distributed along feeder lines 202, power network 200A includes one or more substation buses 204, circuit breakers 206, automatic circuit reclosers (ACRs) 208, sectionalizers 210, electrical switches 212 (e.g., with voltage transformers), and/or other cable accessories.

In accordance with techniques of this disclosure, power network 200A includes a monitoring system 214A configured to collect and process data indicative of one or more conditions of the power network. As described herein, monitoring system 214 includes a central computing system 220, and at least one monitoring node 222 operatively coupled to feeder lines 202. In some examples, power network 200A may include at least one “secondary” monitoring node (not shown) operatively coupled to feeder lines 202 at some distance away from the monitoring nodes 222, e.g., greater than about 5 meters away from a monitoring node 222, or greater than 10 meters away, or greater than 25 meters away.

As detailed further below, monitoring nodes 222 may include one or more monitors, sensors, communication devices, and/or one or more power-harvesting devices, which may be operatively coupled to insulation screen 106 (FIG. 1A and FIG. 1B) of the cable 202 to perform a variety of functions. The one or more sensors (e.g., monitors) can output sensor data indicative of conditions of the cable 202 or a proximate cable accessory. Examples of such sensors include temperature sensors, partial-discharge (PD) sensors, reflectometers, smoke sensors, gas sensors, and acoustic sensors, among others.

According to further aspects of this disclosure, computing system 220, such as a remote computing system and/or a computing device integrated with one or more of monitoring nodes 222, determines a “health” of the cable and/or cable accessory based at least in part on the coupling and/or other sensor data. For example, computing system 220 may, e.g., in real-time, determine whether a cable accessory will fail within a predetermined amount of time based at least in part on the sensor data. By determining a health of the cable accessories and predicting failure events before they occur, computing system 220 may more-quickly and more-accurately identify potential failure events that may affect the distribution of power throughout the power grid, or worker and/or civilian safety, to name only a few examples. Further, central computing system 220 may proactively and preemptively generate notifications and/or alter the operation of power network 200A before a failure event occurs.

As indicated by dashed lines 226 in FIG. 2, each monitoring node 222 includes a direct data connection with central computing system 220. For instance, each monitoring node 222 may communicate data with central computing system 220 via any or all of a wireless data communication, a mesh network, an Ethernet network, fiber optic cables, or a direct electrical integration (e.g., common electrical circuitry) with central computing system 220.

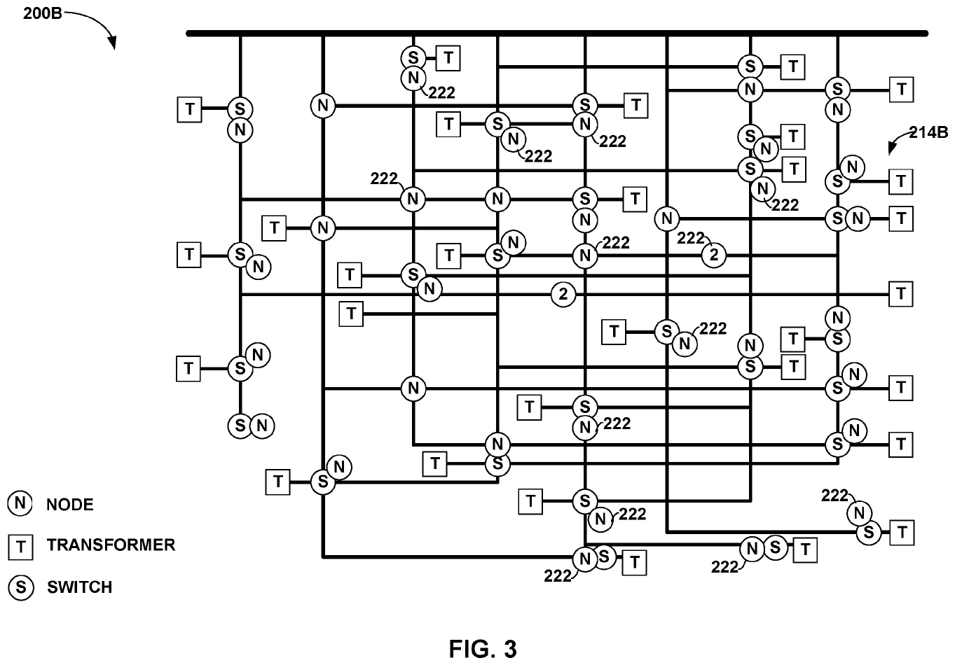

FIG. 3 is a conceptual block diagram illustrating another example electrical power network 200B that includes a distributed, hierarchical network of monitoring nodes. More specifically, power network 200B of FIG. 3 represents a “mesh” power grid, e.g., electrically coupled to a power source (not shown) and configured to supply electrical power to a geographic region (or any subdivision thereof, including a city, a city block, or even an individual building).

In the example illustrated in FIG. 3, electrical power network 200B (also referred to herein as “power grid 200B”) is fitted with a monitoring system 214B that includes a plurality of monitoring nodes 222. Additionally, power grid 200B includes a plurality of transformers (labeled “T” in FIG. 3) and electrical switches (labeled “S” in FIG. 3). As illustrated in FIG. 3, power grid 200B includes a relatively dense coverage of monitoring nodes 222, particularly at or near cable accessories or other devices, along relatively continuous stretches of the cables 202 themselves, and at cable branches or cable intersections. The dense coverage of the grid enables highly precise sensor measurements and grid monitoring, e.g., any measurements made or detected by sensors of a monitoring node can only be associated with a relatively small region of the grid, providing for rapid and precise localization should any anomalies arise.

As described herein, grid-monitoring systems 214A, 214B, via sensors coupled to and/or incorporated within monitoring nodes 222, are configured to collect data that indicates one or more of a health of a component of an electric powerline; one or more environmental conditions at the respective monitoring node 222; a state or operability of electrical grid 200B comprising the electric powerline; a presence of a fault in the electric powerline; or a location of a fault in the electric powerline.

In accordance with techniques of this disclosure, monitoring nodes 222 are operatively coupled to a cable 202 and communicatively coupled to central computing system 220, and are configured to acquire a first sensor data and to acquire a second sensor data different from the first sensor data, and to deliver the first sensor data and the second sensor data to central computing system 220. In some examples, the first and second data may be a single data point at a single point in time, or a plurality of data points over a period of time, e.g., time-series data, a signal, or any data or information associated with grid-monitoring systems 214A, 214B, cables 202, and/or any field devices coupled to or associated with electrical power networks 200A, 200B.

In some examples, but not all examples, in addition to monitoring conditions of grid 200B, monitoring system 214B is further configured to control field devices associated with power grid 200B. For instance, monitoring system 214B, via local monitoring nodes 222, may be configured to locally monitor and control the configurations (e.g., tap positions) of one or more of electrical switches, transformers, capacitor banks, or the like.

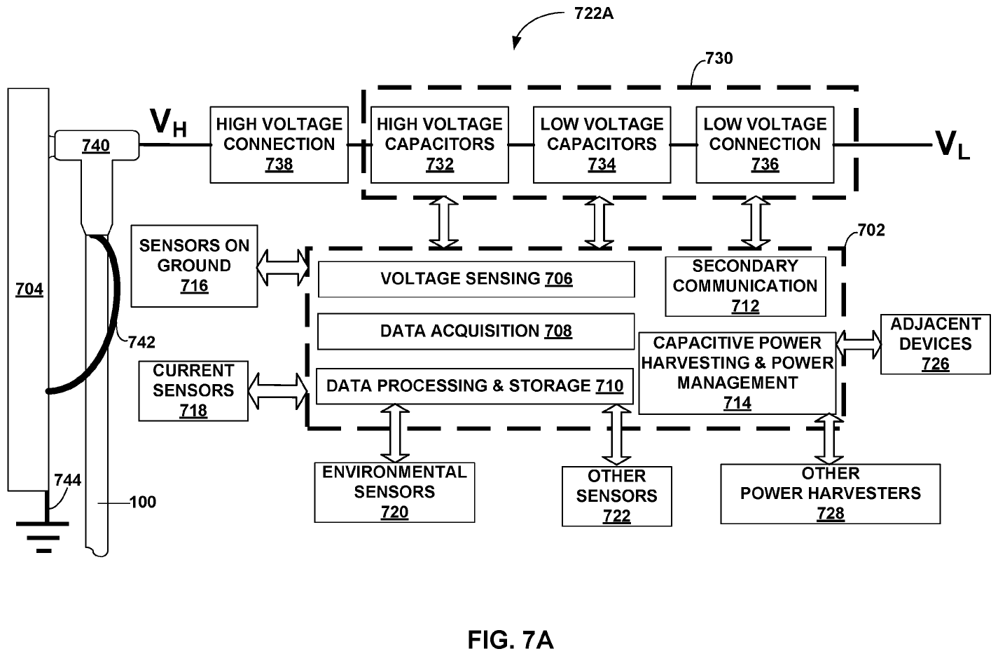

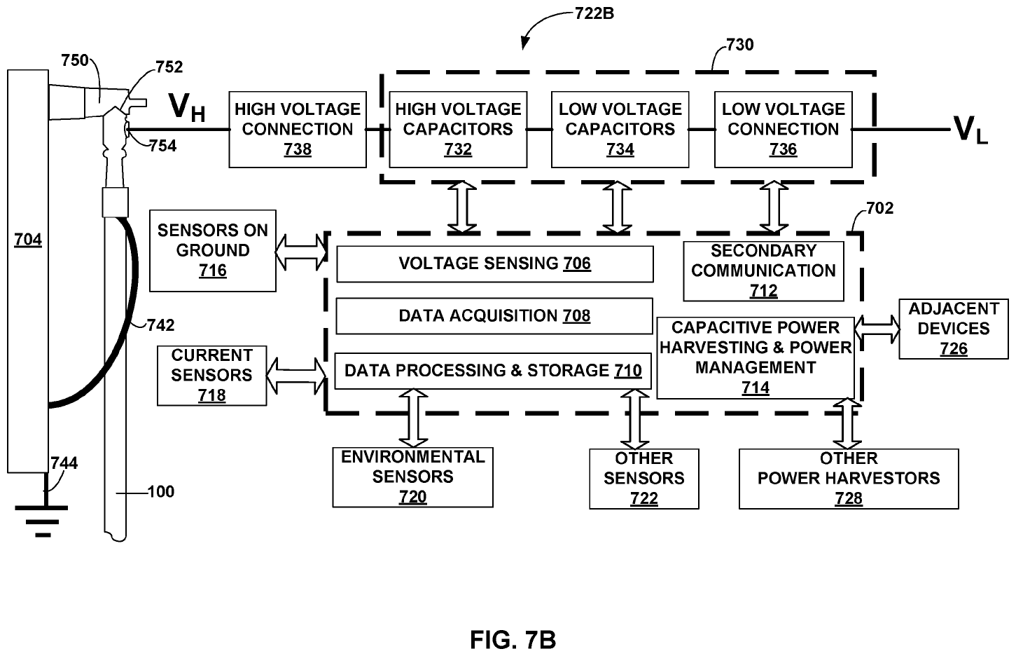

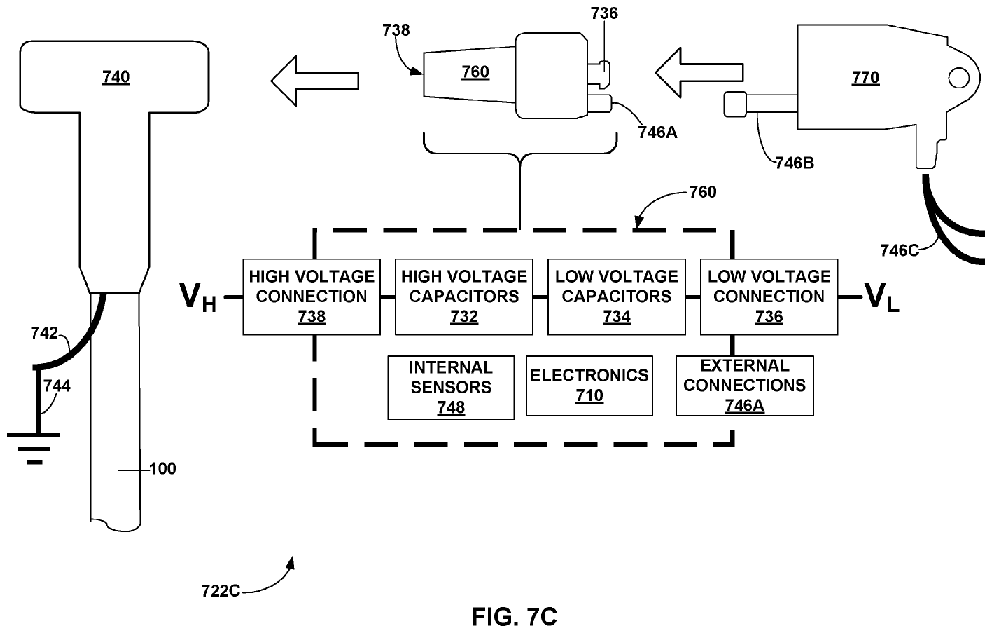

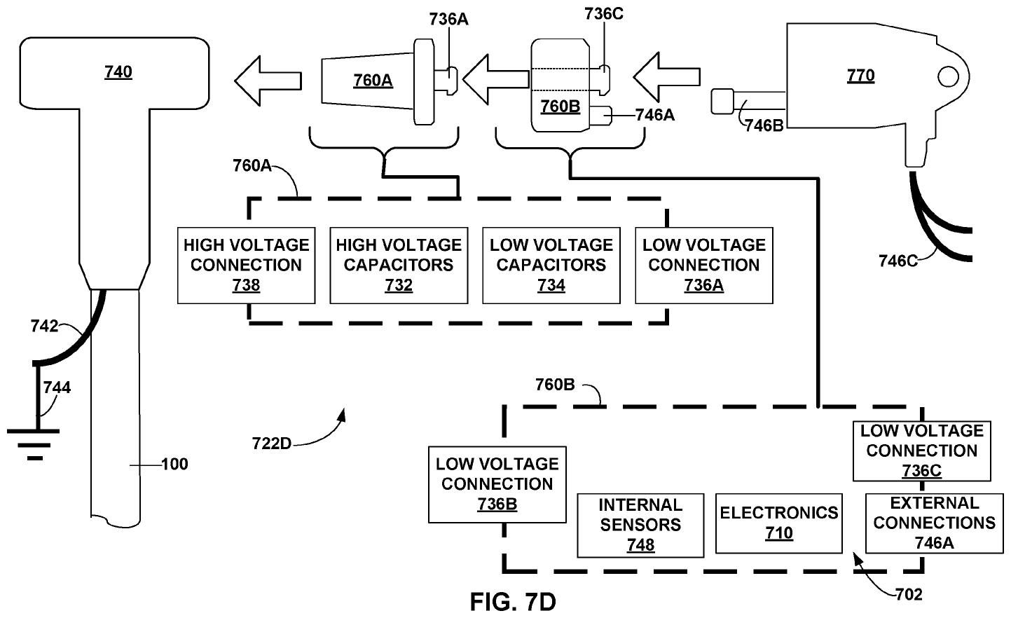

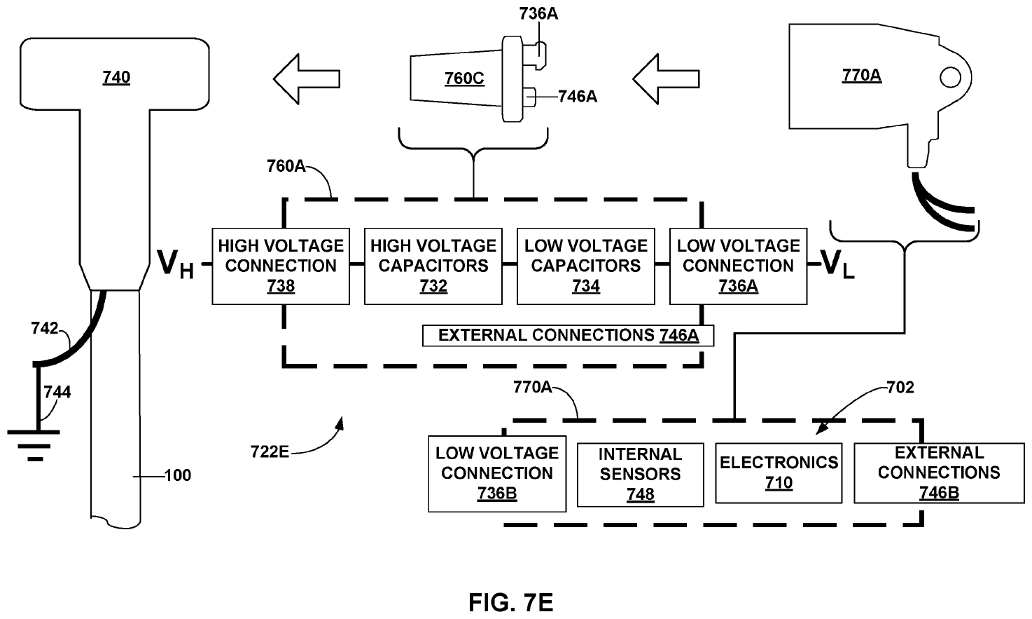

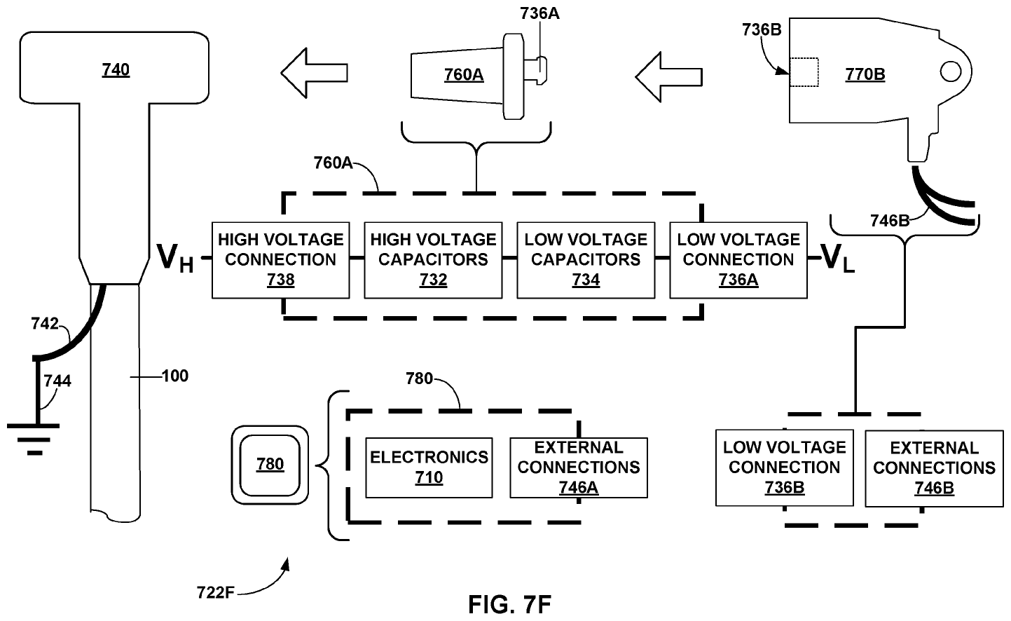

As described herein, in some examples, one or more techniques of this disclosure may include effectively converting or “upgrading” an electrical power network (e.g., grid 200B) into both a power network and a data-communication network. For instance, as detailed further below with respect to FIGS. 7A-7F, monitoring system 214B (and in particular, monitoring nodes 222) is configured to operatively couple to one or more electronic devices, in order to provide both electrical power and data-communication capabilities for the electronic device(s). Examples of such electronic devices may include sensors, cameras, or computing device(s), e.g., having intended functionality that may or may not be associated with monitoring conditions of power network 200B.

For example, as shown and described below with respect to FIGS. 7A-7F, monitoring nodes 222 (and/or distinct connector devices 740, 750) may include integrated data-communication interfaces, such as fiber-optic data interfaces, wired data interfaces, wireless data interfaces (e.g., for device-to-device data communication), or powerline communication (“PLC”) couplings (e.g., for connecting directly to the network). Data communicated via these interfaces may or may not be associated with monitoring conditions of (or controlling) power network 200B. Additionally or alternatively, electronic devices may be coupled to a different electrical component (e.g., a cable accessory coupled to the powerline), e.g., that is located “upstream” or “downstream” from a monitoring node 222 of system 214B. Once appropriately connected, the electronic device(s) may then communicate data via the powerline, for instance, via the powerline-communication techniques enabled by the respective monitoring node(s).

For instance, in a first illustrative example, a (human) user may submit user input via a user interface (e.g., keyboard, touchpad, display) of an electronic device that is operatively coupled to monitoring system 214B as described above. Monitoring system 214B then communicates the user input to a remote device (e.g., central system 220 or another monitoring node 222) via the data-communication techniques described herein.

In a second illustrative example, monitoring nodes 222 of monitoring system 214B may be configured to “actively” handle information-access requests (e.g., web pages or other web client-server requests) between two or more locations. In a third illustrative example, a server or computer can “passively” send information along the network of monitoring nodes 222 to another (e.g., remote) computing device, with minimal or no active processing by any of the monitoring nodes 222 involved.

In a fourth illustrative example, an “independent” data network (e.g., an integrated security system or climate-control system for a building) may either partially interface, or fully integrate, with powerline monitoring system 214B such that monitoring nodes 222 can provide some or all of the data-processing functionality of the independent data network. Such techniques may reduce the number of distinct devices needed to operate the independent data network and/or eliminate the need for an indirect connection to a power source.

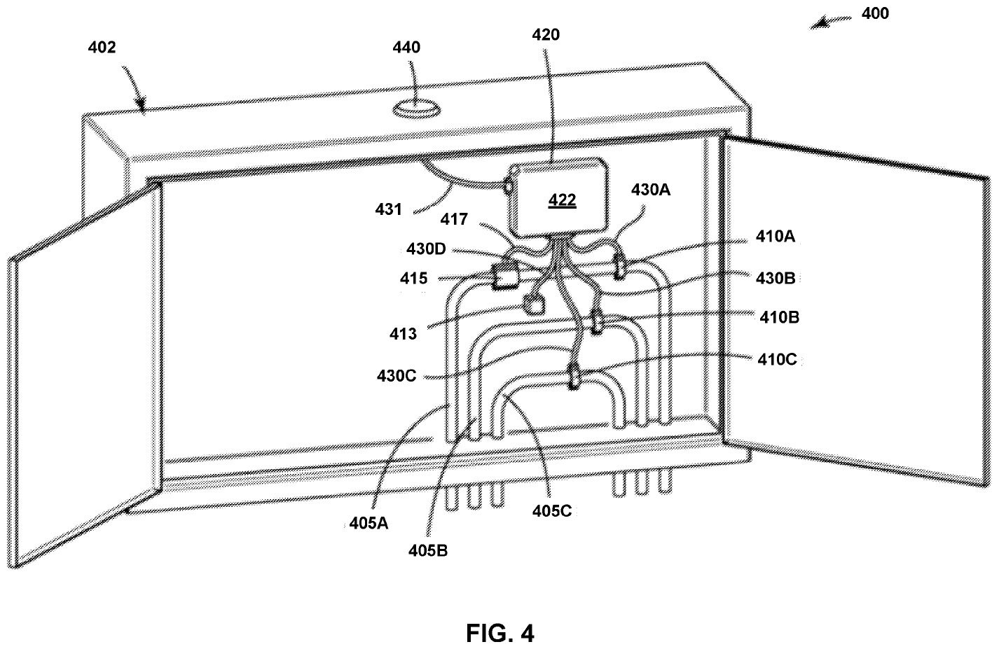

FIG. 4 is a schematic view of one example configuration for a portion of a an electrical-network-monitoring system 400, which is an example of monitoring system monitoring node 400, which is an example of monitoring systems 214A, 214B of FIGS. 2-3. In particular, FIG. 4 illustrates an example enclosure or housing 402 for a monitoring node 420, which is an example of any of monitoring nodes 222 of FIGS. 2-3.

In some examples, monitoring nodes 420 may be implemented as underground communication devices, as described in commonly assigned U.S. Pat. No. 9,961,418 (incorporated by reference in its entirety herein), By contrast, in the example configuration depicted in FIG. 4, monitoring node 420 includes a pad-mounted data-communication system configured to be positioned in an above-ground environment, such as where low, medium, or high-voltage cables enter from the underground and are exposed within the grade-level equipment.

For example, monitoring node 420 may include one or more sensor(s) 410A-410C, e.g., operatively coupled to cable splices, and a transceiver housed an above-ground transformer enclosure 402. Some example grade-level or above-ground devices that can utilize one or more of these monitoring nodes 420 include, e.g., power or distribution transformers, motors, switch gear, capacitor banks, and generators. In addition, one or more of these monitoring-and-communication systems 400 can be implemented in self-monitoring applications such as bridges, overpasses, vehicle-and-sign monitoring, subways, dams, tunnels, and buildings.

As described above, the monitoring devices 420 themselves, or in combination with a sensored analytics unit (SAU), can be implanted in electrical systems requiring low-power computational capabilities driven by, e.g., event occurrences, event identifications, event locations, and event actions taken via a self-powered unit. Further, an integration of GPS capabilities along with time-synchronization events leads to finding key problems with early detection with set thresholds and algorithms for a variety of incipient applications, faults, or degradation of key structural or utility components. Another variable is non-destructive mechanical construction, which could be utilized in fairly hazardous applications.

FIG. 4 illustrates one non-limiting example of such an enclosure or housing 402 for a monitoring node 420 that can be implemented at-grade or above-ground. In this example implementation, enclosure 402 houses one or more electrical lines, such as electrical lines 405A-405C (carrying, e.g., low, medium, or high-voltage electrical power). In other examples, enclosure 402 could house a capacitor bank, motor, switch gear, power or distribution transformer, a generator, and/or other utility equipment.

Enclosure 402 also includes at least one monitoring node 420 disposed therein, which can monitor a physical condition of the vault or of the components or equipment located in the vault. For example, in this example, a current sensor (410A-410C), such as a Rogowski coil, that produces a voltage that is proportional to the derivative of the current, is provided on each electrical line 405A-405C. Additionally, an environmental sensor 413 may also be included. Other sensor devices, such as those described above, can also be utilized within enclosure 402.

Raw data signals can be carried from the sensors via signal lines 430A-430C to sensored analytics unit (SAU) 422 of monitoring node 420. The SAU 422 can be mounted at a central location within the enclosure 402, or along a wall or other internal structure. The SAU 422 includes processing circuitry, such as a digital-signal processor (DSP) or system-on-a-chip (SOC) to receive, manipulate, analyze, process, or otherwise transform such data signals into signals useable in a supervisory control and data acquisition (SCADA) system (e.g., central computing system 220 of FIG. 2). In addition, the DSP can perform some operations independently of the SCADA. For example, as described above, the DSP of monitoring node 420 can perform fault detection, isolation, location and condition monitoring and reporting. Moreover, the DSP/SAU can be programmed to provide additional features, such as, for example, Volt, VAR optimization, phasor measurement (synchrophasor), incipient fault detection, load characterization, post-mortem event analysis, signature-waveform identification and event capture, self-healing and optimization, energy auditing, partial discharge, harmonics/sub-harmonics analysis, flicker analysis, and/or leakage current analysis.

In addition, the DSP and other chips utilized in SAU 422 can be configured to require only low power levels, e.g., on the order of less than 10 Watts. In this aspect, SAU 422 can be provided with sufficient electrical power via a power-harvesting coil 415 that can be coupled, via power cable 417, to one of the electrical lines 405, In addition, the SAU 422 can be implemented with a backup battery or capacitor bank (not shown in FIG. 4).

Processed data from SAU 422 can be communicated to computing system 220 (e.g., a computing network or SCADA) via a transceiver 440. In this aspect, transceiver 440 can include fully integrated, very-low-power electronics (e.g., an SOC for detecting time-synchronous events), along with GPS and versatile radiocommunication modules. Transceiver 440 can be powered by a powerline power source within the enclosure 402, a battery source, or via wireless power (such as via a wireless power transmitter, not shown). SAU 422 can communicate to the transceiver 440 via direct connection with a copper cable and/or fiber cabling 431.

In this example, the transceiver 440 can be mounted directly onto the top (or other) surface of the enclosure 402. The transceiver 440 can communicate with internal enclosure components, such as the SAU 422, via cables 430A-430C. The transceiver 440 can perform network connection, security, and data-translation functions between the outside and internal networks, if necessary.

In another aspect, SAU 422 of primary monitoring node 420 can be configured as a modular or upgradeable unit. Such a modular unit can allow for dongle or separate module attachment via one or more interface ports. As shown in FIG. 4, multiple sensors (410A-410C, 413) are connected to SAU 422. Such a configuration can allow for the monitoring of powerlines and/or a variety of additional environmental sensors, similar to sensor 413, which can detect parameters such as gas, water, vibration, temperature, oxygen-levels, etc.). For example, in one alternative aspect, sensor 413 can comprise a thermal-imaging camera to observe a temperature profile of the environment and components within the enclosure. The aforementioned DSP/other chips can provide computational capabilities to interpret, filter, activate, configure, and/or communicate to the transceiver 440. Dongle or connector blocks can house additional circuitry to create an analog to digital front end. The dongle or connector blocks can also include a plug-n-play electrical circuit for automatically identifying and recognizing the inserted sensing module (and automatically set up proper synchronization, timing, and other appropriate communication conditions).

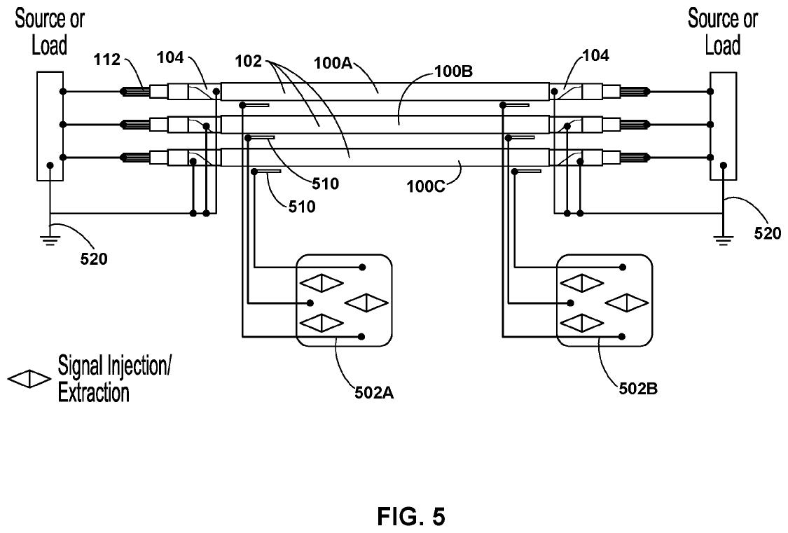

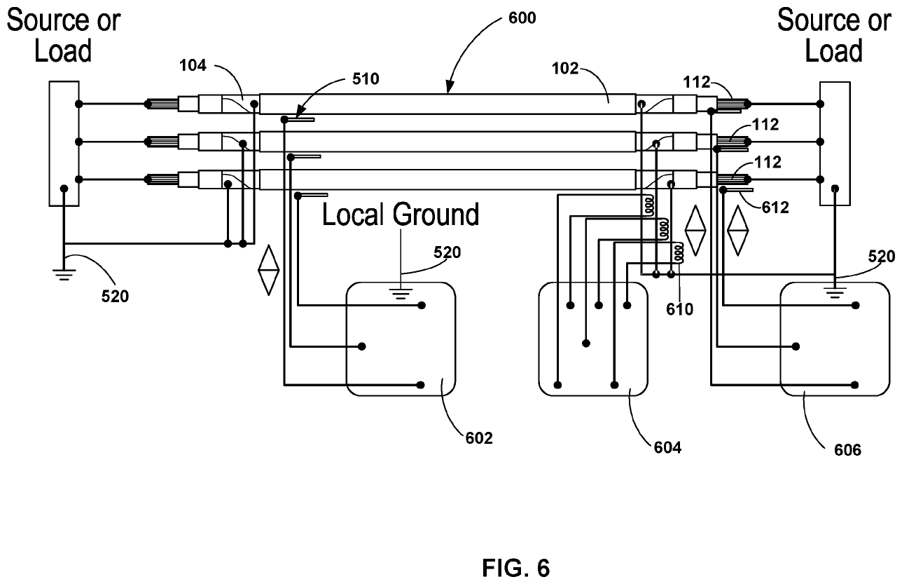

FIGS. 5 and 6 illustrate example implementations of powerline-communication techniques that monitoring nodes 222 (and/or secondary nodes, not shown) may use to directly transmit and receive data with other nodes of a power-network system. For instance, as described above, secondary monitoring nodes may have reduced or more-limited data-communication capabilities compared to monitoring nodes 222, such that, in some cases, secondary monitoring nodes may only be configured to communicate data to other nodes through the powerline to which the respective secondary node is coupled. In some examples, monitoring nodes 222 may be configured to communicate data to other nodes through the powerline to which the respective monitoring node 222 is coupled. Accordingly, FIGS. 5 and 6 illustrate techniques for operatively coupling nodes, e.g., monitoring nodes 222 and/or secondary nodes, to an electric powerline, such that the monitoring nodes 222 may inject signals into the powerline and extract signals from the powerline. However, the examples shown in FIGS. 5 and 6 are merely exemplary of applications for enabling powerline communications. In other examples, monitoring nodes 222 (and/or secondary nodes) of this disclosure may be operatively coupled to a powerline through other techniques.

In examples of this disclosure, a retrofittable monitoring device/node 502A, 502B (collectively, “monitoring nodes 502”), which may be examples of monitoring nodes 222 of FIGS. 2-3 (or secondary monitoring nodes), includes a coupling layer 510 that can support the other functionalities that either inject or extract “intentional” signals or those that extract “unintentional” or “native” signals (e.g., partial discharge signals) that can be indicative of impending failure of the cable 100. Intentional signals that support the functionalities above include pulses or chirps that can help characterize the powerline (e.g., time-domain reflectometry (TDR) or frequency-domain reflectometry (FDR)) or time-synchronization signals that synchronize timing between one location and another. Unintentional or native signals of interest on the powerline include the AC waveform and anomalies embedded within the AC waveform, or partial discharges (PDs), for example. In addition, because both native and intentional signals are subject to noise interference, a coupling mechanism that eliminates at least some noise is beneficial.

In general, the example systems, devices, and/or techniques described herein can provide a retrofittable coupling mode for cable 100 that can support communication along cable 100 to other parts of a network; a coupling that can support various functionalities for infrastructure monitoring where intentional signals are injected and/or extracted and native signals are extracted; a coupling method that reduces noise; combinations of the retrofit cable communication capability with at least one function and noise reduction; and/or a coupling that supports more than one function.

The signals described herein, including both unintentional native signals (e.g., PD) and intentional signals (e.g., communication signals, FDR, TDR), may typically include radiofrequency (RF) signals, which lie in the frequency range of about 0.1 to about 100 MHz. Within this frequency range, cable 100 can be considered as a coaxial transmission line, that includes a central conductive core 112, a dielectric insulating layer 108, insulation layer 106, and a coaxial conducting shield 104 being grounded at one or both of the cable ends. In such a system, at a distance far enough from the ends, the electric potential on both the core conductor 112 and the shield 104 will oscillate relative to ground. Consequently, the signal may be detected by capacitively coupling to the shield 104, e.g., by wrapping a conducting layer 510 (e.g., a conductive metal foil) over the cable jacket 102, thereby creating a coupling capacitor that includes the shield 104, the jacket dielectric 102, and the conducting layer 510.

In examples described herein, a monitoring node 502A, 502B may be operatively coupled to a powerline via either a “single-ended” coupling technique or via a “differential” coupling technique. In a single-ended coupling technique, the monitoring node is capacitively or inductively coupled to an electrical cable at one end (e.g., to the cable shield 104 or to the central conductor 112 of the cable), and coupled to a local ground 520 at the other end. In some such examples, the monitoring node is configured to detect an RF signal within the electrical cable by measuring (e.g., via an RF amplifier of the monitoring node) the potential difference between the cable and the local ground 520. In other such examples, the monitoring node is configured to detect the RF signal within the electrical cable by measuring (e.g., via a current amplifier of the monitoring node) the current running through the cable coupling. In the present description, such implementations are referred to as “single-ended.”

In a differential coupling technique, such as the example illustrated in FIG. 5, a monitoring node 502A, 502B is operatively coupled (e.g., inductively or capacitively) to two different cables 100 of a powerline (e.g., via the cable shields 104 or via the central conductors 112). In the non-limiting example shown in FIG. 5, the monitoring node 502A is physically coupled (via coupling layer 510) to the outer jackets 102 of cables 100, and capacitively coupled (via coupling layer 510) to the cable shields 104 located underneath the jackets 102. If three cables 100A-100C are available, then there are three potential cable pairs (100A, 100B), (100B, 100C), and (100A, 100C) across which monitoring node 502A may be coupled. In multi-cable cases having a number “n” of cables 100 wherein n>3, then there are n*(n-1)/2 unique possible combinations of cable pairs (e.g., any pair of two cables) that may be selected from among the n cables 100, or in other words, choosing 2 cables out of n cables, commonly referred to in combinatorial mathematics as “n choose 2,” or “n-nCr-2”). The communication signal can be multiplexed or repeated on these multiple pairs. This signal can be extracted from a similarly coupled communication device located at a remote location. Each monitoring node 502 can sense locally and communicate information or can act as a repeater to send the information along, or act as a concentrator to collect the information and then send the information to a central location.

As shown in FIG. 5, a monitoring node 502 may be capacitively coupled to at least two separate cables (e.g., 100B, 100C) associated with two different phases. These cables 100B, 100C can be of the same three-phase group or can be unrelated single phases. Monitoring node 502A may include a voltage or current amplifier, and may then be connected between the two coupling capacitors 510, thus measuring the potential difference or the current flowing between them. Such an implementation does not require an independent ground, and so entails a “floating” installation that can be easily coupled onto the cable system. Furthermore, a differential approach will be insensitive to any common-mode noise picked up by the system. For example, in a three-phase system (FIGS. 5 and 6), the three cables 100A-100C are laid as a bundle, and accordingly, the cables will pick up approximately the same electromagnetic noise, which a differential setup will then reduce or cancel out. Similarly, if the phases are not in the same three-phase system, the cables can also have similar pick-up.

Another feature of the capacitive coupling to the cable shield 104 is that this approach allows a straightforward approach to inject RF signals into the cable system, e.g., by applying an RF voltage between the coupling capacitor and the ground 520, e.g., for a single-ended system, or differentially between cable pairs. The injected signals may be received similarly to the method used for native signals, as described above. The injection and pickup of such intentional signals may be used for various purposes, such as: communication between devices; time synchronization between devices; time-domain reflectometry (TDR) or frequency-domain reflectometry (FDR) to detect and localize defects, faults and structural changes in the cable system; channel characterization (e.g., frequency dependent loss, propagation delay); and grid configuration/mapping.

In addition, intentional signals may be injected into more than one channel, e.g. into two or more cables 100 or cable pairs. Such a multichannel approach allows an increased communication bandwidth and/or enhanced communication reliability.

In some examples, monitoring nodes 502 may include, or may be, current amplifiers. For instance, current amplifiers may be used for coupling, where two capacitors 510 on each cable 100 are capacitively coupled to the shields 104, e.g., via physical coupling of a foil layer 510 onto outer jackets 102. Such examples require separate pairs of capacitors per differential channel, thus preventing unwanted signal leakage between the channels. An alternative is to use one capacitor 510 (e.g., conductive foil layer) for each power cable 100 with a high-impedance voltage amplifier (rather than a low-impedance current amplifier) where multiple amplifiers can connect to each foil capacitor 510.

FIG. 6 is a schematic diagram of another example differential coupling system 600 according to techniques of this disclosure. FIG. 6 depicts a more general example of differential or single-ended capacitive coupling to cable shields 104, and also other couplings on the same line or lines to extract or inject other signals of interest (e.g., a communication signal). This other coupling can be single-ended (ground reference) or differential (reference to another voltage).

For instance, FIG. 6 depicts three example cable-monitoring devices 602, 604, and 606 (e.g., monitoring nodes 602, 604, 606). Cable-monitoring device 602 is capacitively coupled to cable shield 104, via a physical coupling 510 overtop of cable jacket 102 (or a cable splice, if present). Cable-monitoring device 602 is an example of a differential or single-ended functional device.

Cable-monitoring device 604 is inductively coupled to cable shield 104, via a physical connection 610 to a wired connection to a local ground 520. Cable-monitoring device 604 is an example of a device that is differential between phases, or a “differential-one-phase-each (DOPE)”functional device.

In some instances, any two (or more) nodes 602, 604, 606, each of which may be an example of a monitoring node 222 (or in some examples, secondary nodes), may locally communicate (e.g., via direct powerline communication) a set of data that is necessary for making a “shared” decision or measurement. As used herein, a “shared measurement” refers to a measurement of a signal (and associated analytics) that is indicative of a condition commonly shared by two or more nodes and/or a section of cable located directly between the two or more nodes. Similarly, a “shared decision” refers to a determined action that affects a condition commonly shared by two or more nodes and/or a section of cable located directly between the two or more nodes. The shared decision may be determined based on, or in response to, a shared measurement.

For instance, monitoring nodes 602 and 604 may be configured to, when necessary, directly exchange information in order to localize the origin of a partial-discharge signal along a section of the shared cable 600 that is directly in between monitoring nodes 602, 604. In such examples, the data analysis (e.g., the PD-localizing) may be performed locally on any or all of the nodes, such that the “raw” data does not need to be transmitted to central computing system 220, thereby increasing available bandwidth resources along both a specific datalink (e.g., between a monitoring node 222 and the central computing system 220) as well as across the large-scale power network as a whole. In some examples, a monitoring node 602, 604, 606 may be configured to locally monitor or “track” cable parameters, without reporting the sensed data to other nodes or the central computing system 220, unless and until the node identifies an above-threshold change in the monitored parameter, thereby further conserving transmission bandwidth and “upstream” processing power.

In some examples, monitoring nodes 602, 604, 606 of the powerline monitoring system are configured to perform cable diagnostics. For instance, any of monitoring nodes 602, 604, 606 may be configured to inject a signal into cable 600. The signal may either be reflected back to the originating monitoring node 602, 604, 606, or may be transformed within cable 600 and received at a different monitoring node 602, 604, 606. In either case, the receiving monitoring node 602, 604, 606 may use the received signal to assess certain parameters or characteristics of cable 600, such as (but not limited to) a condition (e.g., age-based deterioration) of insulation layer 108 (FIG. 1A), the presence of any defects in the conductor 112, or the locations of joints, taps, or faults within cable 600.

By using this type of injected-signal technique (or other methods, such as auto-correlation of native signals) the powerline monitoring system can determine both general system health and local cable health. As used herein, the “health” can refer to a general condition of the cable (e.g., without reference to a particular anomaly at a particular location along the cable), or in other examples, can refer to the health of the cable at a particular site or in a defined section of the cable that is being sampled via the injected signal.

Some non-limiting examples of health-related cable-monitoring through intentional signal injection include identifying fault-based conductor breaks in conductor 112, damage or breaks to the outer shield layer 102 (e.g., due to animals, corrosion, digging, etc.), the presence of water-uptake at or near insulation 108, local temperature increases and/or associated damage, and other irregularities. Because many of these examples may include relatively slowly emerging conditions, the monitoring nodes (e.g., monitoring nodes 222, 502, 502B, 602, 604, and/or 606) described herein may be configured to perform ongoing periodic or continuous monitoring to identify condition changes over time. Additionally, as described above, the distributed monitoring node techniques of this disclosure allows for a highly dense coverage of a power system with monitoring nodes; accordingly, local-cable-monitoring techniques through intentional signal injection may be performed with even higher precision and/or accuracy.

In some examples, monitoring nodes 602, 604, 606 of the powerline-monitoring system may be configured to perform “mapping” of the power network. For instance, the powerline-monitoring system may determine whether monitoring node 602 is operatively coupled to the same cable 600 as node monitoring 604, e.g., by injecting a unique signal into cable 600 at monitoring node 602 and determining which other monitoring nodes 604, 606 detect the signal.

Additionally or alternatively, the powerline-monitoring system (e.g., either at central computing system 220, or via processing circuitry of any of the individual monitoring nodes) may compare detected voltage and/or current spikes, or other similar detected anomalies, between any two nodes to determine whether the two nodes are coupled to the same cable 600. In some such examples, the system may additionally be configured to estimate (e.g., map) a physical distance between the two nodes, e.g., if the two nodes are internally synchronized and both the signal-propagation velocity and a time delay (e.g., duration between detection at each node) are known.

In other examples, e.g., in which the physical distance between two nodes and the signal “time of flight” (e.g., transmission duration) are known, the powerline-monitoring system can determine a propagation delay between the two nodes, any or all of which may then be used for both general-level cable-health analytics, local cable-health analytics.

For instance, any or all of an electrical impedance of cable 600, the signal-propagation velocity, and the time-of-flight of the signal between the two monitoring nodes may be dependent on the dielectric constant of insulation layer 108, which may change over time due to deterioration or damage to the insulation layer. Accordingly, the powerline-monitoring system may use local intentional signal-injection techniques (e.g., using either a reflected signal for a single monitoring node, or using a transmitted signal between two monitoring nodes), to determine these types of characteristics of cable 600, which may be used as a proxy for the dielectric constant of the insulation layer 108 to monitor the general health of cable 600.

Additionally or alternatively to the general-health analytics techniques described in the previous example, the powerline-monitoring system may use similar techniques to perform local-cable-health analytics. For example, in scenarios in which the powerline-monitoring system identifies the presence of a defect or other local damage to cable 600, the system can determine an approximate location of the defect, e.g., either by measuring the physical distance to the defect or by measuring the time-of-flight of an injected signal to that defect. In some examples, if the propagation velocity can be established on the cable (by knowing the time of flight and the actual distance for one or more particular structures like a termination point), then the distance to a defect can be estimated so that corrective action can be taken.

Additionally or alternatively to any of the above examples, similar (e.g., intentional-signal-injection-based) techniques may be used to determine any or all of an electrical impedance of cable 600, a physical length of cable 600 or subsections thereof, and the “branching” of cable 600 (e.g., via mapping, as described above). The powerline-monitoring system may then use these parameters to produce a virtual simulation (or “digital twin”) of an electrical power system (e.g., the power network or power grid that includes cable 600).

Similarly, the powerline-monitoring system may use intentional signal injection via monitoring node(s) 602, 604, 606 to synchronize the various nodes of the system. For instance, the system may inject, via any of the primary or secondary nodes, intentional signals such as “pulses” or “chirps” to perform time-domain reflectometry (TDR) (or time-domain reflectometry), frequency-domain reflectometry (FDR) (or frequency-domain reflectometry), or other similar time-synchronization signals that synchronize timing between two or more monitoring nodes, In various examples, the system may be configured to use individual (e.g., relative) timing signals, or in other examples, maintain a universal clock for all nodes 602, 604, 606.

In the example shown in FIG. 6, cable-monitoring device 606 is capacitively coupled (via coupling 612) directly to central conductor 112, or adjacent to central conductor 112. Cable-monitoring device 606 is an example of a single-ended functional device (and of monitoring nodes 222, or secondary monitoring nodes). This type of coupling 612 directly to central conductor 112 may be achieved through the use of an intermediary connector device, as described and illustrated with respect to FIGS. 7A-7F.

For instance, FIGS. 7A-7F are six illustrative examples of monitoring nodes such as monitoring nodes 222 of a power-network-monitoring system, in accordance with techniques of this disclosure. In particular, each of FIGS. 7A-7F includes a block diagram illustrating an example arrangement of sub-components of a monitoring node 222, as well as a schematic view of an example coupling mechanism for operatively coupling the respective monitoring nodes 222 to an electric powerline of a power network or grid. For example, FIGS. 7A-7F illustrate monitoring nodes 722A-722F, respectively, each of which may be an example of monitoring nodes which may be used with electrical power networks 200A, 200B of FIGS. 2-3.

FIG. 7A includes a block diagram illustrating a first example arrangement of sub-components of monitoring node 722A, where the arrangement of sub-components is configured to electrically couple a set of “functional” sub-components 702 to an article of electrical equipment 704 of a power-delivery system. As shown in FIG. 7A, the functional sub-components 702 of monitoring node 722A include one or more of a voltage-sensing unit 706, a data-acquisition unit 708, a data-processing-and-storage unit 710 (e.g., processing circuitry), a “secondary” communication unit 712, and a capacitive-power-harvesting-and-power-management (CPHPM) unit 714. The functional sub-components 702 are generally configured to receive and process signals generated by various sensors of monitoring node 722A. As shown in FIG. 7A, these various sensors may include one or more of ground sensors 716, electrical-current sensors 718, environmental sensors 720, or other sensors 722.

In some examples, the functional sub-components 702 (and/or other adjacent devices 726) may additionally receive electrical power from other power harvesters 728, e.g., other than via a coupling to a component 704 of the power network. For instance, as shown in FIG. 7A, monitoring node 722A includes a high-voltage capacitive coupling unit 730 configured to electrically couple the functional sub-components 702.

In some examples, monitoring node 722A is removably coupled to a component 704 of an electric-power network via a separable T-body connector 740. As shown in FIG. 7A, T-body connector 740 includes three ports configured to mutually electrically couple (1) a power cable 100 of an electric powerline; (2) an article of electrical equipment 704, such as a cable splice, cable termination, etc.; and (3) monitoring node 722A. T-body connector 740 further includes a ground connection 742 to an electrical ground 744, e.g., of electrical equipment 704.

FIG. 7B includes a block diagram illustrating a second example arrangement of sub-components of monitoring node 722B, which is an example of monitoring node 722A of FIG. 7A, except for the differences noted herein. In particular, FIG. 7B illustrates that, instead of T-body connector 740 of FIG. 7A, monitoring node 722B is electrically coupled to electrical equipment 704 and power cable 100 via a removable elbow-type connector 750. For instance, unlike the more-rigid T-body connector 740, elbow connector 750 may include a hinge 752 allowing for modification of an angle between the electrical couplings of equipment 704, power cable 100, and monitoring node 722B. As used herein, “removable” refers to the property that elbow connector 750 is not rigidly coupled to electrical equipment 704. In some examples, but not all examples, monitoring node 722B may be rigidly electrically coupled to elbow connector 750 via a port 754 on a backside of elbow connector 750.

FIG. 7C includes a block diagram illustrating a third example arrangement of sub-components of monitoring node 722C, which is an example of monitoring node 722A of FIG. 7A and/or monitoring node 722B of FIG. 7B, except for the differences noted herein. In particular, FIG. 7C illustrates an example in which monitoring node 722C is physically separable into at least two distinct components: a plug 760 and an end cap 770.

In the example shown in FIG. 7C, the primary electronics 710 (e.g., processing circuitry and memory) and sensors 748 of monitoring node 722C are housed within plug 760, configured to removably and electrically couple (e.g., via high-voltage connection 738) to one of the three coupling ports of T-connector 740 of FIG. 7A. A backside of plug 760 includes two coupling ports: a low-voltage connection port 736, and an external-connections port 746A for coupling monitoring node 722C to other devices (e.g., external sensors, etc.). Low-voltage connection port 736 additionally functions as an electrical “test point,” enabling a user to connect an external device (e.g., a voltmeter or other device) to determine (via activation of the connected device) whether power cable 100 is currently energized while plug 760 is coupled to the T-connector 740.

In the examples shown, monitoring node 722C further includes a removable end cap 770 configured to fit over a back side of plug 760. In the example depicted in FIG. 7C, end cap 770 is configured to cover (e.g., prevent access to) low-voltage connection port 736 while coupled to plug 760. By comparison, end cap 770 includes an external electrical connection 746B configured to electrically couple to external electrical connection port 746A of plug 760. External electrical connection 746B is routed through end cap 770, such that external electronic devices may still be electrically connected to plug 760 while end cap 770 is removably coupled to plug 760.

FIG. 7D includes a block diagram illustrating a fourth example arrangement of sub-components of monitoring node 722D, which is an example of monitoring nodes 722A-C of FIGS. 7A-C, respectively, except for the differences noted herein. Similar to the example depicted in FIG. 7C, external connections 746B of monitoring node 722D may be routed through end cap 770. However, unlike plug 760 of FIG. 7C, which is depicted as a single, physically coherent unit, monitoring node 722D of FIG. 7D includes plug 760A and a removable extension module 760B. In this example, the primary electronic coupling mechanism (for coupling to T-connector 740) is housed within plug 760A; however, the actual “functional” sub-components 702 of monitoring node 722D are housed within extension module 760B, which functions as an intermediary coupling component between electrical-connector plug 760A and end cap 770.

FIG. 7E includes a block diagram illustrating a fifth example arrangement of sub-components of monitoring node 722E, which is an example of monitoring nodes 722A-D of FIGS. 7A-D, respectively, except for the differences noted herein. For instance, similar to the example plug 760A depicted in FIG. 7D, the primary electronic coupling mechanism 738 (for electronic coupling to T-connector 740) is housed within removable plug 760C. However, unlike the example monitoring node 722D of FIG. 7D, in which functional sub-components 702 are housed within a removable extension module 760B, in the example monitoring node 722E depicted in FIG. 7E, functional sub-components 702 (including primary electronics 710 and sensors 748) are housed within end cap 770A, which is an example of end cap 770 of FIGS. 7C and 7D.

FIG. 7F includes a block diagram illustrating a sixth example arrangement of sub-components of monitoring node 722F, which is an example of monitoring nodes 722A-E of FIGS. 7A-E, respectively, except for the differences noted herein. For instance, monitoring node 722F includes the same example electrical-connector plug 760A depicted in FIG. 7D. Additionally, similar to the examples shown in FIGS. 7C and 7E, end cap 770B is configured to couple directly to electrical-connector plug 760A. However, unlike the previous examples, in the example shown in FIG. 7F, the primary electronics 710 (e.g., processing circuitry and memory) of monitoring node 722F are housed within a processing module 780 that is both, physically distinct from plug 760A and end cap 770B, but also not configured to physically interconnect with either device. Instead, processing module 780 may be configured to receive signals and data, from an external sensor module (not shown), e.g., via short-range wireless communication capabilities, or via a wired connection through external connections port 746A. After processing or analyzing the data, processing module 770B may then transmit the processed data, e.g., via short-range wireless communication capabilities, or via a wired connection through external connections port 746A, to plug 760A for signal injection into cable 100.

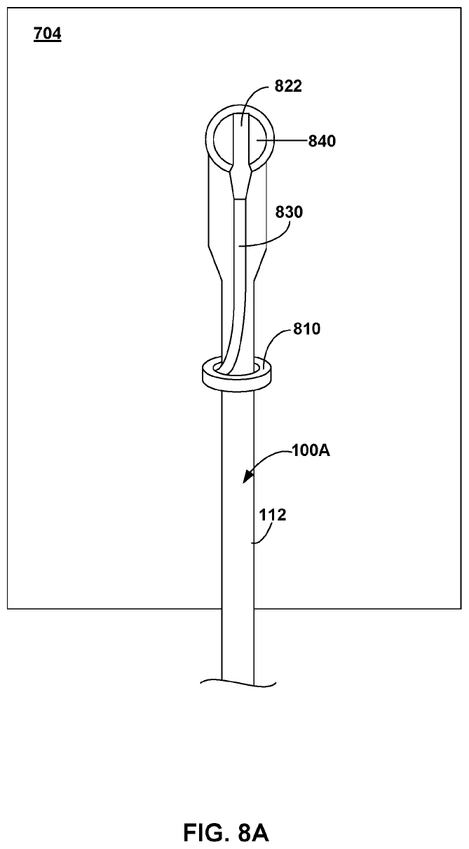

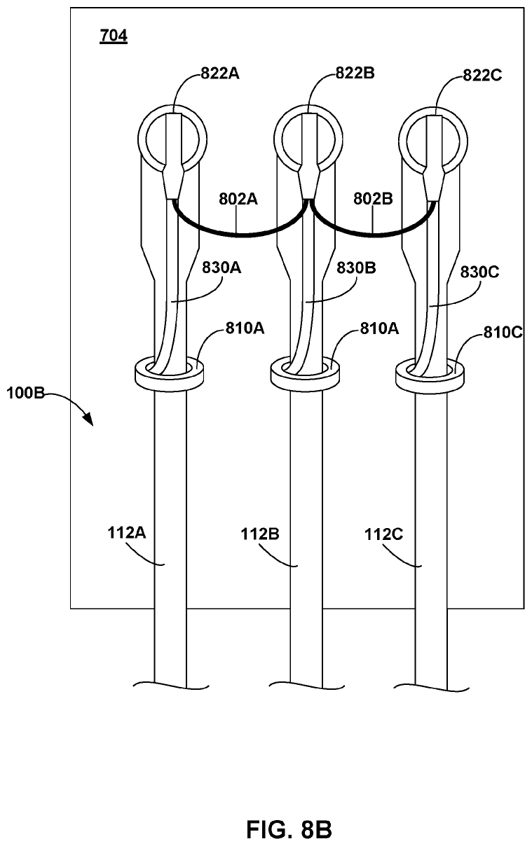

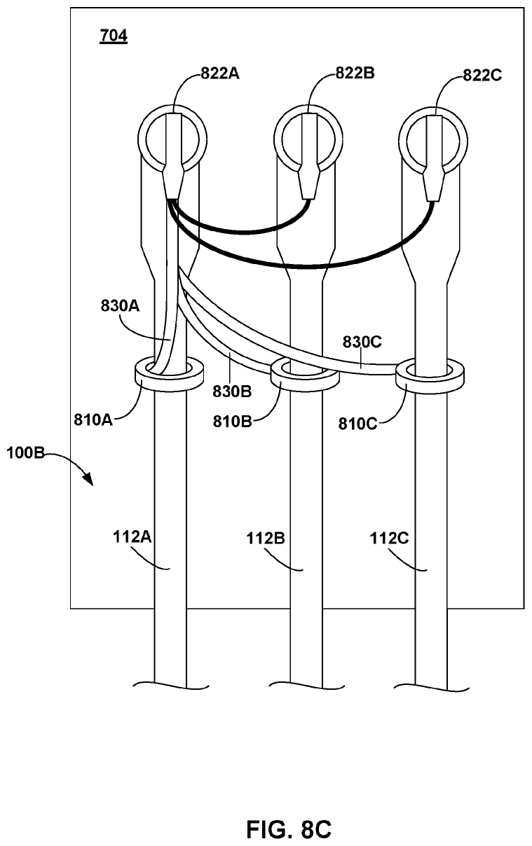

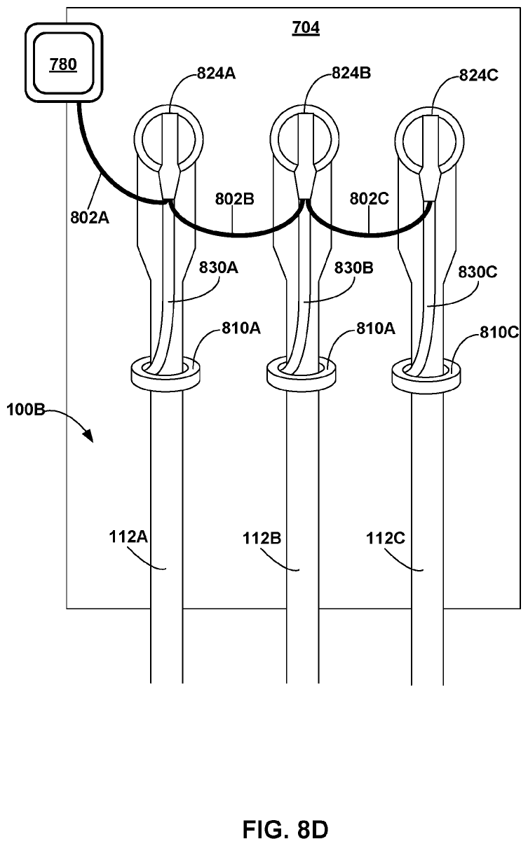

FIGS. 8A-8D illustrate four non-limiting examples of techniques for operatively coupling and/or interconnecting one or more monitoring nodes 822 to different phases of a single electric power cable. For instance, FIG. 8A illustrates a first example technique applied with respect to a single-phase electric-power cable 100A (FIG. 1A), e.g., having only a single central conductor or phase 112. Accordingly, the powerline-monitoring system in this example includes only a single monitoring node 822, which is an example of monitoring nodes 222, 722, above. Similar to the examples depicted in FIGS. 7A-7F, monitoring node 822 is operatively and electrically coupled to both power cable 100A and an article of electrical equipment 704 via a three-port connector 840. Three-port connector 840 may be an example of T-connector 740 of FIGS. 7A and 7C-7F, an example of elbow connector 750 of FIG. 7B, or an example of another similar coupling, such as the capacitive or inductive couplings described above with respect to FIGS. 5 and 6. In the example shown in FIG. 8A, monitoring node 822 further includes a current sensor 810 (e.g., a Rogowski coil) coupled to signal line 830, which are examples of current sensor 410 and signal line 430, respectively, described above with respect to FIG. 4.

FIG. 8B illustrates a second example technique applied with respect to a multi-phase electric-power cable 100B (FIG. 1B), e.g., having three conductors or phases 112A-112C. Accordingly, the powerline-monitoring system in this example includes three distinct monitoring nodes 822A-822C, each monitoring node having its own current sensor 810A-810C, respectively.

In the example depicted in FIG. 8B, the three monitoring nodes 822A-822C are locally communicatively coupled to one another. For instance, monitoring node 822A shares data with monitoring node 822B via data cable 802A, and monitoring node 822B shares data with third monitoring node 822C via data cable 802B. In this way, monitoring data can be shared between the three phases of cable 100B, e.g., for timing or for communication redundancy. For example, if more than one phase is coupled to the same electronics, the communication can be sent on two or more lines for redundancy, e.g., if a channel is disrupted, or the signal can be distributed on two or more lines.

FIG. 8C illustrates a third example technique applied with respect to a multi-phase electric-power cable 100B (FIG. 1B), e.g., having three conductors or phases 112A-112C. Unlike the example depicted in FIG. 8B, in which an equivalent monitoring node 822 is deployed on each phase of the power cable 100B, the example depicted in FIG. 8C includes one “active” monitoring node 822A and two “passive” monitoring nodes 822A, 822B. That is, monitoring node 822A houses the primary electronics (e.g., processing circuitry and memory) that primarily govern and process data for all three monitoring nodes 822A-822C. Because active monitoring node 822A performs the processing of data collected by current sensors 810A-810C, signal lines 830A-830C are directly connected between active monitoring node 822A and each of current sensors 810A-810C.

Additionally or alternatively, active monitoring node 822A includes local data connections or other direct couplings 802A, 802B to monitoring node 822B, 822C, respectively. For instance, although “passive” monitoring node 822B, 822C may not be configured to perform primary data processing, the nodes may transfer data and/or power with active monitoring node 822A for other purposes, such as voltage-sensing, powerline communication (e.g., signal injection and/or extraction), and power-harvesting from the various phases of cable 100B.

FIG. 8D illustrates a fourth example technique applied with respect to a multi-phase electric-power cable 100B (FIG. 1B), e.g., having three conductors or phases 112A-112C. Unlike the example depicted in FIG. 8C, which includes one “active” monitoring node 822A and two “passive” monitoring node 822A, 822B, the example deployment of FIG. 8D includes three “passive” monitoring node 822A-822C, communicatively coupled to the physically distinct processing module 780 of FIG. 7F.

For instance, similar to the example in FIG. 8C, processing module 780 includes local data connections or other direct couplings 802A-802C to monitoring nodes 822A-822C such that passive monitoring nodes 822A-822C may perform the more “passive” functions of voltage-sensing, powerline communication (e.g., signal injection and/or extraction).

Additional details and examples of Multimode Sensing System for Medium and High Voltage Cables and Equipment are now described.

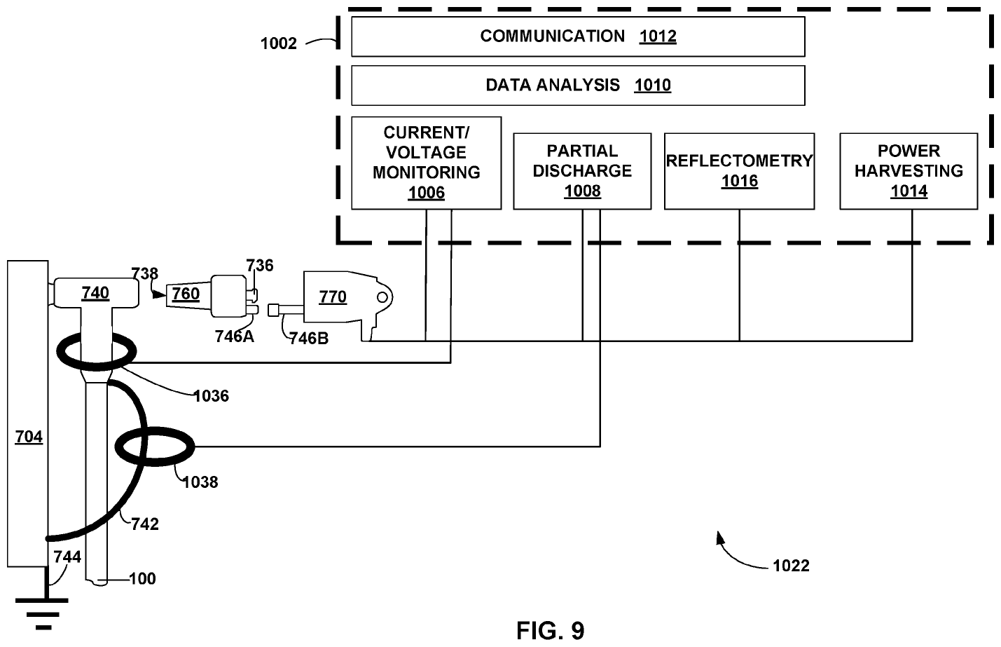

An example of this disclosure may comprise an online, continuous monitoring system that includes a self-powered electronic module that couples electrically with the MV distribution at cable terminations for active and passive sensing and power harvesting (FIG. 9), and includes communication (wireless, wired, fiber optic, etc.) to a central computing system (cloud or on-premises). This module is combined with analytics that are deployed in the monitoring device and in the central computing system. The local analytics are configured to detect the signal, reject noise, extract critical data features and summarize the information, while the central analytics are configured to combine results from multiple nodes for location determination, to store the data, and to improve the solution through learning over many installations. Combined data analysis where the data from one sensing mode is combined with that of another sensing mode or external data like weather can be done in the local device or in central location. In general, the monitoring system is configured to monitor the cable system to detect and alert for specific defective sites or regions of the cable system. In another embodiment, the monitoring tools described herein (e.g., partial discharge) can be used to monitor and report on health aspects of adjacent equipment like transformers, switchgear, and circuit breakers. In some examples, the monitoring tools described herein provide design efficiency and coupling efficiency (e.g., more than one function can be performed through a single coupling site), and may provide a plurality of measurements and/or sensor data with a common timestamp, electronics/processing, and communication. Some of these methods are complimentary in that much greater information can be derived with the combined sensor data than the single sensor data alone.

FIGS. 9-13 are illustrative examples of monitoring nodes such as monitoring nodes 222 of a power-network-monitoring system, in accordance with techniques of this disclosure. In particular, each of FIGS. 9-13 includes a block diagram illustrating additional example arrangements of sub-components of a monitoring node 222, as well as a schematic view of an example coupling mechanism for operatively coupling the respective monitoring node 222 to an electric powerline of a power network or grid, e.g., similar to FIGS. 7A-7F. For example, FIGS. 9-13 illustrate monitoring nodes 1022-1422, respectively, each of which may be an example of monitoring nodes which may be used with electrical power networks 200A, 200B of FIGS. 2-3.

FIG. 9 is a block diagram illustrating an example configuration for a monitoring node 1022 electrically coupled to a power-delivery system via a removable T-body connector 740 and an insulating plug 760. Monitoring node 1022 may be an example of monitoring node 722C of FIG. 7C, except for the differences noted herein,

In the example shown, an arrangement of sub-components is configured to electrically couple a set of “functional” sub-components 1002 to an article of electrical equipment 704 of a power-delivery system. As shown in FIG. 9, the functional sub-components 1002 of monitoring node 1022 include one or more of a communication unit 1012, a data analysis unit 1010, a current and/or voltage-sensing unit 1006, a data-processing-and-storage unit 710 (e.g., processing circuitry), a partial discharge (PD) unit 1008, a reflectometry unit 1016, and a capacitive-power-harvesting-and-power-management (CPHPM) unit 1014. The functional sub-components 1002 are generally configured to receive and process signals generated by various sensors of monitoring node 1022. As shown in FIG. 9, these various sensors may include one or more of inductive couplers 1036 and 1038, electrical-current sensors, environmental sensors, or other sensors.

In the example shown, communication unit 1012 may be configured to communicatively couple monitoring node 1022 to electrical equipment 704 and/or cable 100, e.g., to communicatively couple sub-components 1002 to the powerline. Data analysis unit 1010 may be substantially similar to data acquisition unit 708 and data processing and storage unit 710 described above. Partial discharge unit 1016 may be configured to sense partial discharge signals, and power harvesting unit 1014 may be substantially similar to power harvesting unit 714 described above.

In some examples, monitoring node 1022 is coupled to the power line at a termination point (e.g., with one or three phases per device) through capacitive coupling (through a sensing insulating plug in the example shown) and contains various sensing capabilities, such as power harvesting, e.g., via power harvesting unit 1014. Other sensing and functionality at this device can be included such as environmental sensing (temperature, humidity, gas) or functions to help locate a cable or a defect in the cable or other equipment.

Monitoring node 1022 may include a continuous online monitor with an advantage that an initial scan or “fingerprint” of the cable system may be captured and compared to future scans to determine the relative magnitude of a particular defect and/or condition, and the rate of any change in its severity or size. For example, for faults, the defect can be an abrupt change, while for asset health, the rate of change of defect severity and/or condition can be gradual, and may have periods of rapid growth. A scan interval, e.g., period of time between acquiring sensor data, may be decreased (e.g., to increase sensing frequency) when a defect and/or condition is rapidly changing. In addition, monitoring node 1022 may be configured to operate as a combined multimodal sensor to provide a reduction (e.g., relative to a single sensor) of false positive alerts by using a plurality of sensor data (e.g., a first sensor data and a second sensor data) from a plurality of sensor modalities together. Monitoring node 1022 may be configured to provide, via combined multimodal sensing, to provide sensing and determination of a broader range of conditions, defects, and the like, and to provide improved accuracy of locating conditions, defects, and the like.

The particular conditions, defects, or events (e.g., partial discharge) to be detected, located and alerted in the cable system (e.g., including the cable and/or any associated devices) may include defects or imperfections that are already severe initially or are minor but increasing in severity, and detecting and locating a fault that has already occurred. In some examples, monitoring device 1022 may sense and/or measure a particular quantity or quantities or a rate of change of those quantities and can alert (e.g., central computing system 220) when either of the quantities or their rates of change exceed a given threshold. In some examples, monitoring node 1022 may be configured to determine a risk assessment based on a comparison to similar conditions, defects, or events on the monitored grid (based on magnitude and rate of change), e.g., for pre-faults, and over time may be configured to provide more accurate risk assessments as central computing system 220 and/or monitoring node 1022 learns about the speed of condition, defect, or event progression across multiple grids with similar conditions, defects, or events. In some examples, monitoring node 1022 may be configured to provide a prediction of the time to failure by pattern and causality analysis, e.g., via learning over time using a plurality of sensed/measured defect examples (such as in a controlled or field environment),

In some examples, monitoring node 1022 may provide timely information for a grid operator to take clear action with automated analysis and alerts and without the need for interpretation by on-site or remote experts. In some examples, monitoring node 1022 may provide low false positive and false negative rates so that confidence in the system and its recommendations are high and are acted upon to avoid failure. In some examples, a user interface of an electronic device that is operatively coupled to monitoring node 1022 (which may be through central computing system 220) may be configured to be simple and as integrated as possible with the operator's management system or with a relatively simple alerting system through mobile devices (e.g., a mobile phone, laptop computer, or the like) or as input to the maintenance workorder creation system or dispatcher.

In the example shown, multiple sensing modes include reflectometry via reflectometry unit 1016, e.g., FDR and/or TDR, partial discharge via partial discharge unit 1008, voltage and current monitoring, via current/voltage monitoring unit 1006, and other sensing modes, e.g., temperature, humidity, gas, and the like. The multiple sensing modes may be complementary and may be used to monitor different types of defects substantially concurrently (e.g., intemal void in a cable splice via PD, broken neutrals via reflectometry, and fault occurrence via voltage/current sensing) and to increase an accuracy in locating and/or gauging condition, defect, or event severity relative to sensing a single sensing mode.

For example, monitoring node 1022 may be configured to acquire reflectometry data via FDR by injecting a sweep of frequencies into a cable and/or the grid at a location, and then acquire (e.g., sense, measure, detect) the reflected signal. Reflectometry unit 1016 may be configured to map any impedance changes along the “probed” portion of the powerline. For example, impedance changes may occur with changes in the cable geometry or insulating materials properties (such as water in the insulation). Reflectometry unit 1016 may be configured to acquire multiple FDR scans over time, and the causes of impedance changes may be detected and located. In some examples, reflectometry unit 1016 may be configured to acquire sensor data indicative of defects such as broken or damaged neutrals, open conductors, shunt faults and/or other structural changes in the powerline cable via reflectometry, e.g., FDR and/or TDR.

In the example shown, monitoring node 1022 may be configured to acquire PD data. For example, PD unit 1008 may configured to acquire (e.g., sense, measure, detect) electrical discharge that partially spans a distance between high and low voltage electrodes in an energized system. In some examples, PD unit 1008 may be configured to acquire sensor data indicative of partial discharges arising from internal voids in the insulation, which may be the result of a manufacturing defect or an installation error in a cable splice. Partial discharge is not only a symptom of a defect, is also a damage-causing process that causes defect growth and can eventually lead to dielectric breakdown under voltage, and ultimately, catastrophic failure of at least a portion of a powerline. Internal voids may be point defects, and PD unit 1008 may be configured to acquire data from which such point defects may be detected and analyzed, and to provide insight into the severity and location of such defects.

In the example shown, monitoring node 1022 may be configured to acquire voltage and/or current data. For example, voltage/current unit 1006 may be configured to acquire (e.g., sense, measure, detect) voltage and/or current signals of the powerline. In some examples, the voltage and/or current data may be complementary with PD from a given source or sources. In some examples, monitoring device 1022 and/or central computing system 220 may be configured to construct a Phase Resolved Partial Discharge Plot (PRDP) plot using voltage and/or current data and PD data. A PRDP plot may comprise PD occurrence(s), and optionally PD magnitude, plotted versus the AC power cycle. In some examples, voltage/current unit 1006 may be configured to acquire voltage and/or current data indicative of passage of a fault current and the direction to the fault. In some examples, e.g., for pre-fault detection, voltage/current unit 1006 may be configured to acquire voltage and/or current data indicative of subcycle waveform anomalies that may be indicative of self-clearing or incipient faults that are sometimes precursors to a permanent fault. For example, voltage/current unit 1006 may be configured to acquire the waveforms, and voltage/current unit 1006, monitoring node 1022, or central computing system 220, may be configured to analyze the waveforms and determine if the waveforms are consistent with a cable system related emerging fault. Voltage/current unit 1006, monitoring node 1022, or central computing system 220 may be configured to then determine a distance to the pre-fault, e.g., including impedance estimations and time-of-flight to two spanning monitoring stations.

In some examples, voltage/current unit 1006 may be configured to acquire voltage and/or current data indicative of transient voltage and/or current events, e.g., due to subcycle arcing in a cable system, and monitoring node 1022 and/or central computing system 220 may be configured to combine the voltage and/or current data with other sensor data, e.g., acquired partial discharge, at the same location to provide high confidence that the event and damage progression is real and also to determine whether the site is progressing toward imminent failure, and to provide reduced false positives in reporting such events. In some examples, monitoring node 1022 and/or central computing system 220 may be configured to improve both identification of the location of a condition, defect, or event via a plurality of acquired sensor data of different types, times, and/or locations.

In some examples, monitoring node 1022 may be configured to acquire other sensor data, e.g., locally measured temperature, and to provide alerts for other conditions, defect, or events, such as overheating connectors. For example, monitoring node 1022 may be configured to acquire sensor data indicative of a sufficiently high temperature hot spot along the cable, e.g., via reflectometry. The hot spot may indicate a resistive connection that may cause failure of a joint or termination over time. Monitoring node 1022 and/or central computing system 220 may be configured to determine, via a plurality of sensed data (e.g., FDR, TD, temperature) identification and alerts for conditions, defects, or events with a higher degree of certainty, including, for example, defect severity and its risk of future failure. In some examples, monitoring node 1022 and/or central computing system 220 may be configured to determine a risk of future data including a plurality of sensor data and other data, e.g., current loading and its effect on defect severity over time). In some examples, if a temperature rise at the hot spot is correlated to the current in the line over cycles of rising and falling current, then resistive heating can be suspected as the root cause, and monitoring node 1022 and/or central computing system 220 may be configured to use increases in the intensity of heating with the same current to determine and/or alert for damage progression and impending failure.

In the example shown, several of the sensing modalities (e.g., current, voltage, PD, reflectometry) interface with the power system through an electrical coupling and/or interface, such as a capacitive electrical connection or one or more inductive couplings, at a cable termination via monitoring node 1022. This provides a common and available interface in most distribution systems and supports the multiple functions with a single (or combined) physical interface. In the example shown, monitoring node 1022 includes plug 760. In the example shown, inductive coupler 1036 may be a Rogowski coil for sensing a powerline current, and inductive coupler 1038 may be a high frequency current transformer (HFCT) for sensing partial discharge on ground connection 742, e.g., as an alternative to sensing a partial discharge to the capacitive electrical connection (e.g., plug 760), or to additionally sense a partial discharge (e.g., along with plug 760).

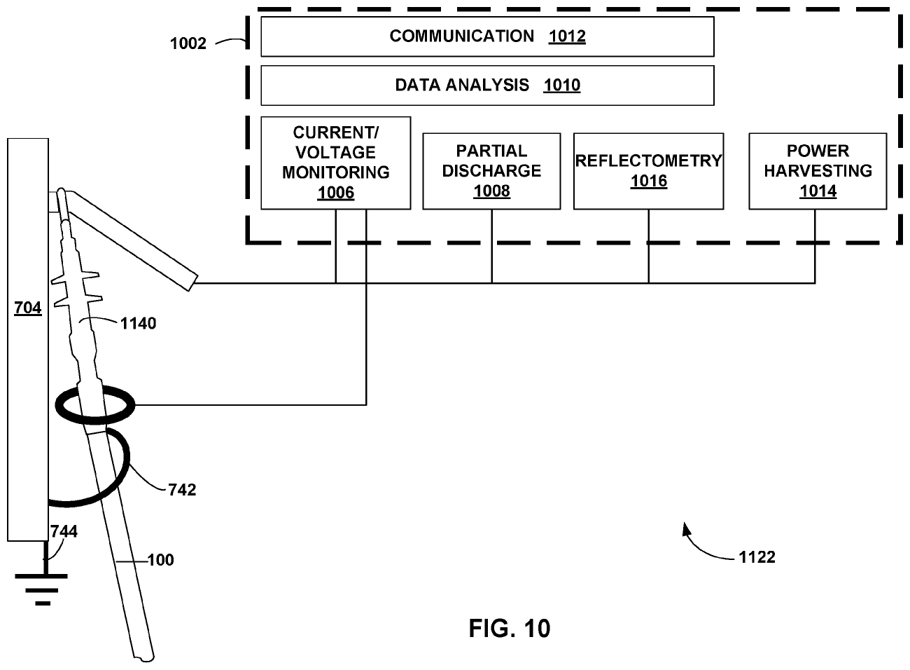

In some examples, coupling sensors to a power grid with the fewest components (e.g., monitoring nodes) for the full functionality is advantageous for total cost reduction, streamlined installation, and ease of maintenance. These types of terminations may be located at transformers and switchgear in the grid and may be utilized for the monitoring system. Instead of using an insulating plug interface at a separable connection as shown, other capacitive coupling techniques may be used, including single or multiple capacitors in parallel at a cable termination location within the equipment at the connection point (e.g., a bushing), or integrated with a live front termination (as shown in FIG. 10).

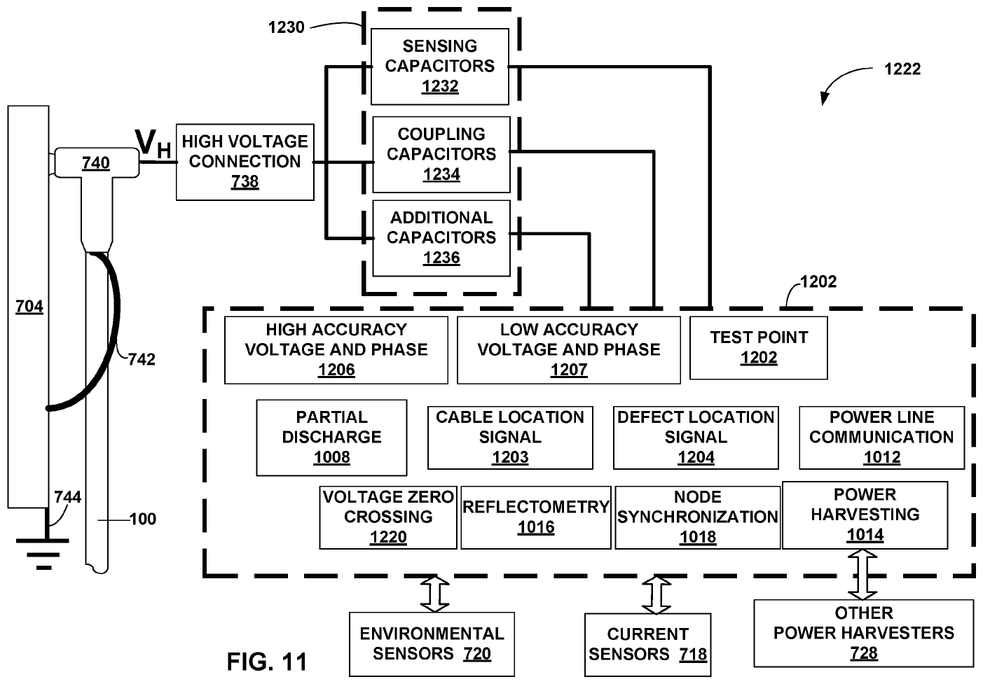

FIG. 10 is a block diagram illustrating an example configuration for a monitoring node 1122 electrically coupled to a power-delivery system via a live front termination 1140. Monitoring node 1122 may be substantially similar to monitoring node 1022, except that monitoring node 1122 may be coupled to the power-delivery system via a live front termination 1140. FIG. 11 illustrates an alternative physical interface to the insulating plug. The capacitive element or elements can be embedded within the termination or within the equipment.

FIG. 11 is a block diagram illustrating another example configuration for a monitoring node 1222 electrically coupled to a power-delivery system via a removable T-body connector 740. Monitoring node 1222 may be an example of monitoring node 722A of FIG. 7A, except for the differences noted herein. In the examples shown, the configuration for monitoring node 1222 is configured to electrically couple a set of “functional” sub-components 1202 to an article of electrical equipment 704 of a power-delivery system.

In the example shown, monitoring node 1222 includes capacitive coupling unit 1230, which may be substantially similar to capacitive coupling unit 730 of FIG. 7A, except that capacitive coupling unit 1230 includes sensing capacitors 1032, coupling capacitors 1234, and optionally additional capacitors 1236. Sensing capacitors 1232 may be a capacitor or a plurality of capacitors in series, and high accuracy voltage and phase unit 1206 may be configured to acquire sensor data comprising high accuracy voltage and phase via sensing capacitors 1232. For examples, sensing capacitors 1232 may include more robust, higher accuracy capacitors configured to have a reduced variation. Coupling capacitors 1234 may be a capacitor or a plurality of capacitors in series (e.g., different from the capacitor and/or capacitors of sensing capacitors 1232). In the example shown, sensing capacitors 1232, coupling capacitors 1234, and optionally additional capacitors 1236 of capacitive coupling unit 1230 are connected to the medium-or high-voltage of the powerline and/or power-delivery system in parallel. Each of sensing capacitors 1232, coupling capacitors 1234, and optionally additional capacitors 1236 may support one or more of sub-components 1202. In some examples, sensing and/or functional modalities (e.g., PD, FDR, power harvesting, phase/frequency & low accuracy voltage) may connect through a low accuracy, high value, high voltage capacitor, while high accuracy voltage uses a high accuracy, low value, high voltage capacitor.

Sub-components 1202 may be an example of any of sub-components 702 of FIG. 7A or sub-components 1002 of FIG. 9, except for the differences noted herein. In the example shown, sub-components 1202 additionally includes high accuracy voltage and phase unit 1206, low accuracy voltage and phase unit 1207, test point 1202, cable location signal unit 1203, defect location signal unit 1204, and voltage zero crossing unit 1220.

Monitoring node 1222, e.g., via capacitive coupling unit 1230 and sub-components 1202, may be configured to acquire (e.g., monitor, measure, sense, detect) a plurality of sensor data and perform a plurality of monitoring functions. For example, monitoring node 1222 may be configured to acquire sensor data including fault voltage, transient voltage events, PD event quantities, PD waveform characteristics, PD statistics, voltage waveforms and/or characteristics of the waveforms of multiple phases of a powerline, voltage (e.g., root-mean-square voltage, average voltage, maximum and minimum voltage, and the like), voltage phase, the presence of a voltage, power quality measurements and diagnostic (e.g., flicker, harmonic distortion, voltage sag/swell, and the like), power factor, reflected intentional signals and characteristics, diagnostic signal generation (e.g., reflectometry), diagnostic signal reception and analysis, cable location signal generation, defect location signal generation, timing signal generation and reception, communication signal generation and reception (e.g., powerline communications), and the like.

Monitoring node 1222, and/or central computing system 220, may be configured to perform, based on acquired sensor data, any or all of voltage and/or current monitoring, capturing, and analytics, PD monitoring, capturing, and analytics including phase resolution, temperature monitoring of a device and/or nearby components and analytics, distance-to-fault analysis, voltage and/or current waveform anomaly capture and analysis, fault indication and diagnostics, e.g., direction, impedance, and the like), incipient fault detection and analysis, load and load balancing measurements, reactive and active power measurements and analysis, phasor measurement and analysis, asset (e.g., the power grid and/or any associated devices/components) health risk assessment, asset health failure prediction, fault direction analysis, node timing synchronization, cable characterization (e.g., attenuation, impedance, velocity of propagation, and the like), combination and integration of information from more than one monitoring node 1222 at a location, combination and integration of information from another monitoring node 1222 at a different location, cable location via a signal induced by the device (e.g., locating and marking in combination with an above-surface mobile locator), defection location via a signal induced by the device (e.g., locating and marking in combination with an above-surface mobile locator), and the like.

Monitoring node 1222, and/or central computing system 220, may be configured to analyze and determine aspects of power grid state, asset health, and fault response enabling, including, for example, state estimation, faulted segment identification, fault location (estimation and pinpointing), pre-fault site location (estimation and pinpointing), syncrophasor analysis, conservation voltage reduction, volt/VAR control, predictive maintenance, asset risk assessment, load profiling, waveform anomaly classification and learning, asset failure prediction and learning, network connectivity analysis, metering, feeder reconfiguration, cable characterization, safety alert system, cable defect identification with location, PD monitoring, capturing, noise rejection, and analytics, integration of sensor data from a plurality of monitoring nodes for additional insight and/or determinations, e.g., improved determination of defect location, type, severity, etc., and the like.

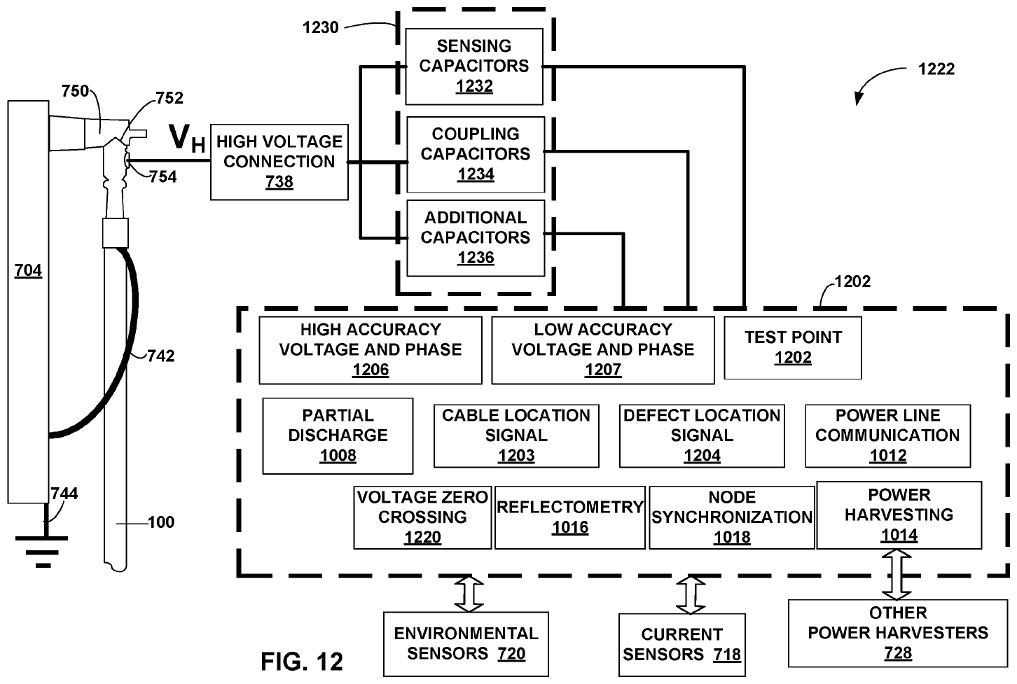

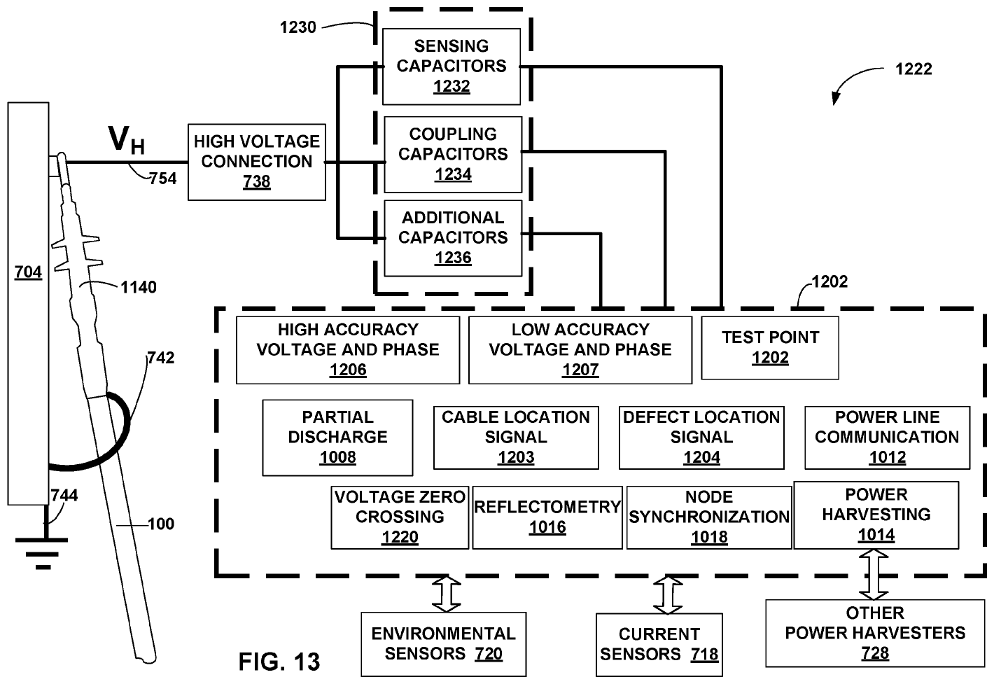

FIG. 12 is a block diagram illustrating another example configuration for a monitoring node 1222 electrically coupled to a power-delivery system via a removable elbow-type connector 750, and FIG. 13 is a block diagram illustrating another example configuration for a monitoring node 1222 electrically coupled to a power-delivery system via a live front termination 1140.

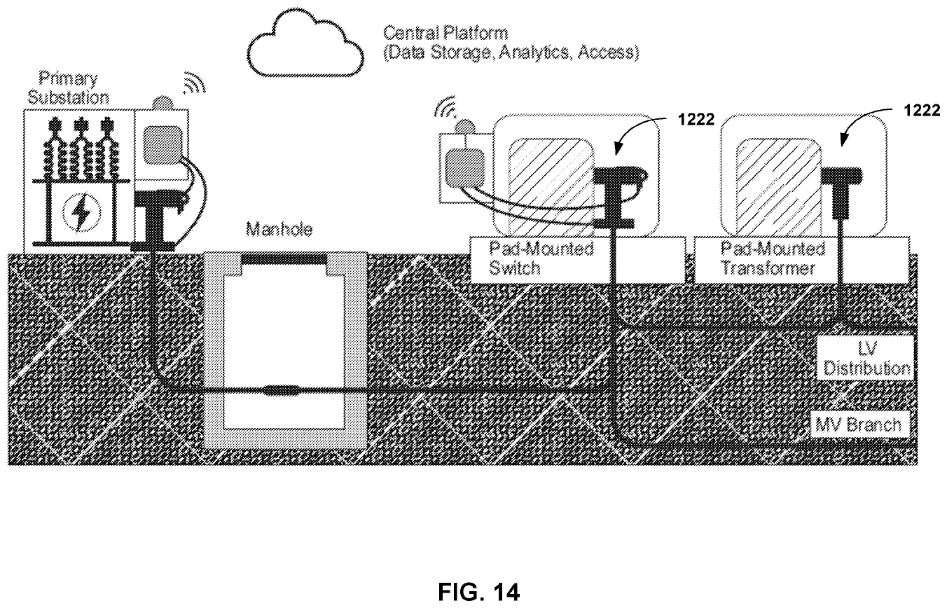

FIG. 14 illustrates a representative deployment of monitoring nodes 1222 at cable termination locations at or near the substation or in pad mounted equipment. The cable system and adjacent equipment may be monitored. Although only monitoring node 122 is shown, FIG. 14 illustrates an example location of where a monitoring node (e.g., any of monitoring nodes 222, 420, 502, 602, 604, 606, 722, 822, 1022, 1122, 1222) may be installed to monitor the distribution lines, but other ways of deploying and integrating are possible also.

In some examples, monitoring nodes disclosed herein, e.g., any of monitoring nodes 222, 420, 502, 602, 604, 606, 722, 822, 1022, 1122, 1222 may provide multimode sensing and functionality, e.g., to provide a plurality of sensor data (a first sensor data, a second sensor data) of the same or different types acquired at the same or different times, and provide a common coupling interface and a combined electronics module. Multiple functions with common coupling provide an economical way to cover the grid and permits a higher density of the monitoring nodes for a given monitoring budget. An increased density of monitoring nodes may improve signal acquisition and sensor data acquisition (e.g., because the cable and equipment along the line and branches may attenuate signals from the reflectometry and PD, which may limit the ability to sense and locate higher frequency signal components or small signals). For example, reflectometry and PD location methods are accurate to some percent of the distance of the monitor and/or sensor to the defect. An monitoring system with an increased density of monitoring nodes decreases the distance from a monitoring node to a defect, and improves location estimation. For example, if a 10 kilometer powerline is monitored, and the location accuracy is 1%, then the location uncertainty is +/−100 meters, if a 500 meter powerline is monitored, then the location uncertainty is +/−5 meters.

In some examples, if two monitoring nodes acquire sensor data of the same defect or event, then increased location accuracy is possible. A further complication of real power grids are branches and switches where the where signals can proceed in multiple directions. Placement of monitoring nodes and/or sensors at each branch may allow for deconvolution of the various signal paths.

In some examples, location accuracy may depend on the cable type and the distance from a monitoring node to the defective areas (fault or pre-fault). Reflectometry may have a different location capability than PD, but the use of a high-density of monitoring nodes and combining and/or synchronizing sensor data of a plurality of monitoring nodes that detect the same event (e.g., a PD, or a fault, or a pre-fault transient) may provide a more accurate distance estimate than one monitoring node and sensor data acquired of the event.

Reference timing may comprise node synchronization between a plurality of monitoring nodes. For example, a reflectometry sensor data acquired by a single monitoring node on one side of a defect may be used to determine a relative distance to the defect if the actual distance to at least one detected impedance change (such as a termination) point may be used for calibration. Alternately, if the cable velocity of propagation is known or may be estimated, then this the cable velocity may be used to convert the measurement to actual distance from the monitoring node location. For PD location, a location estimation along the cable can be determined if the same PD source is detected at two monitoring nodes spanning the defect site and that are synchronized sufficiently to locate the site.

Regarding locating and repair, a distance of a defect along a cable may be estimated, but the actual location to dig and repair the cable (e.g., pinpoint) may not be easy to determine (unless the cable is arranged in a straight path to a remote and visible surface marker and the operator can simply walk the given distance) since the cable may be arranged in an unknown way underground. Pinpointing is typically done using the impulse or thumping (also called acoustic) technique which can degrade the cable and reduce its remaining lifetime (since the high impulse loading can damage the cable insulation along the entire cable length). An estimation of the distance (e.g., via a monitoring system including monitoring nodes disclosed herein) may aid in the location, e.g., the operator may be directed to a location close to the site and impulse (thumping) can be used for a shorter time over a smaller area to reduce damage. Alternatively, if distance is estimated, and the cable sections have already been accurately mapped using GPS (global positioning system), the mapping may be integrated with the monitoring system to automatically identify the segment and the pinpointed defect location.

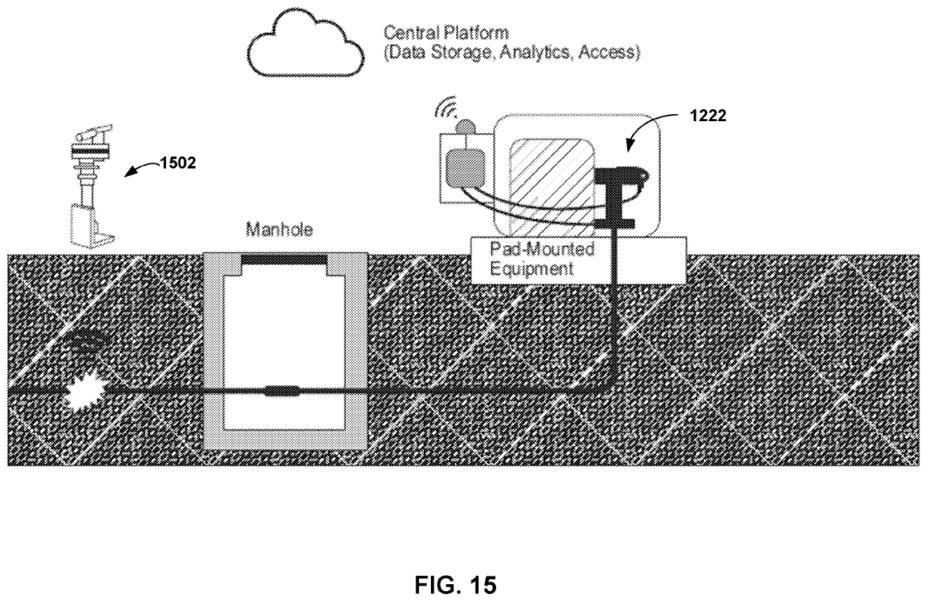

In some examples, an above-surface device may be used to locate a defect in underground cables. FIG. 15 illustrates another representative deployment of a monitoring node 1222 in which monitoring node 1222 may introduce and/or inject a signal that interacts with a defect in the cable, and the interaction may be detectable via a locating device 1502, e.g., a handheld locator, a robotic locator, or other locating device.

For example, monitoring device 1222 may be configured with a toner function, e.g., configured to send and/or inject a signal into the cable and make the cable visible above the surface using a handheld (or robotic) locator 1502 to map the cable at the site before or after a failure. The toner functionality can be turned on from a remote site or locally and an operator may then determine the cable path and go to the location where the system indicates the failure defect is located (e.g., through electrical distance estimation).

In some examples, monitoring node 1222 may be configured to receive a signal from the cable generated by the cable receiving and interfering with, or is induced by, a signal (e.g., an electrical signal) from locating device 1502. In other examples, monitoring device 1222 may be configured to send and/or inject a signal through the common, or other coupling means, that propagates on the cable shield. When the cable shield comes in contact with an unplanned earth ground connection, the signal may be stopped (e.g., no longer present after the unplanned earth ground connection) or is emitted at the defect site. Conductor opens and shorts and other defects may also interact with such an injected signal. The locating device 1502 may then be used to determine the site where the defect is via the injected signal, and to determine where the operator needs to dig to repair the defect/damage. In some examples, an operator of locating device 1502 may trigger a signal to be injected by monitoring node 1222 through local or remote commands via central computing system 220.

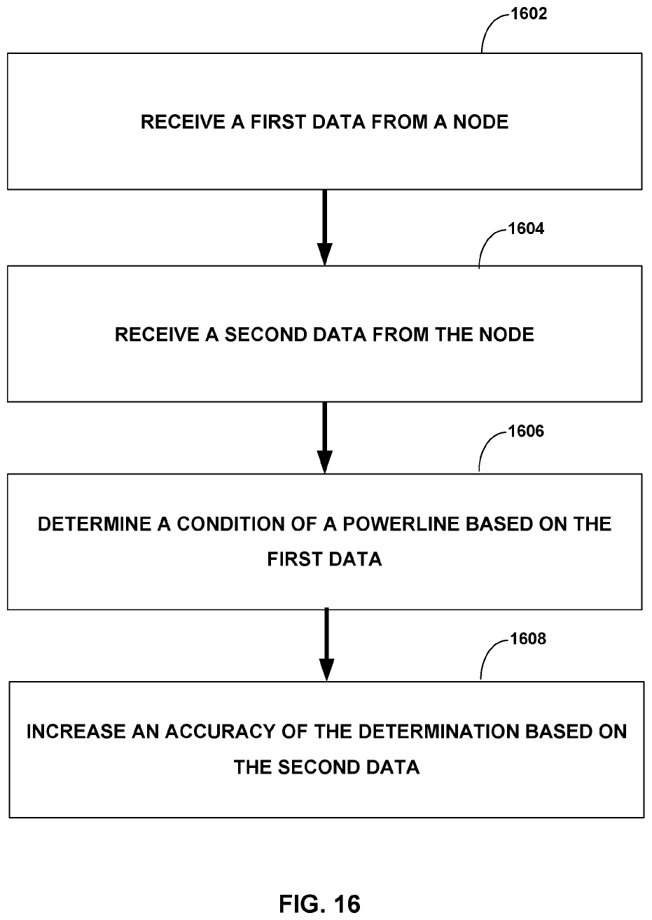

FIG. 16 is a flowchart illustrating example techniques for monitoring an electrical powerline and/or electric power network, in accordance with this disclosure. The techniques of FIG. 16 are described with respect to FIGS. 2, 3, and 11. The techniques include receiving, from a monitoring node 1222, a first sensor data. The monitoring node 1222 may be a monitoring node of a system 214 configured to monitor one or more conditions of an electric powerline 202 comprising one or more electrical cables 100, monitoring data into an electrical cable 100A (FIG. 1A) of the one or more electrical cables 100 to which the monitoring node 1222 is operatively coupled (1602). The first sensor data may be of a first type, e.g., a frequency domain reflectometry, a time domain reflectometry, a partial discharge, a voltage, a current, a temperature, or any data suitable for monitoring a power cable, and may be acquired via one or more sensors of monitoring node 1222.

The techniques of FIG. 16 may further include receiving, from a monitoring node 1222, a second sensor data (1604). In some examples, monitoring node 1222 includes a first sensor configured to acquire both the first and second sensor data. In other examples, monitoring node 1222 includes a first sensor configured to acquire the first sensor data and a second sensor configured to acquire the second sensor data. In some examples, the second sensor data may be from the same monitoring node 1222, or a different one of a plurality of monitoring nodes 1222. In some examples, the second sensor data may be from the same monitoring node 1222, or a different one of a plurality of monitoring nodes 1222. The second sensor data may be the same data type as the first sensor data and acquired at a different time or during a differing period of time, or the second sensor data may be of a different data type than the first sensor data and acquired at the same time or a different time, or during the same time period or a different time period, as the first sensor data.

In some examples, the first sensor data is received from a first monitoring node 1222 coupled to electrical cable 100A at a first location, and the second sensor data is received from a second monitoring node 1222 coupled to electrical cable 100A at a second location. The first and second locations may comprise a termination point of respective cables 100, a branch point of respective cables 100, a respective medium-voltage cable 100, or a cable accessory of a respective cable 100. In some examples, the first monitoring node 1222 at the first location and the second monitoring node 1222 at the second location are configured to send and receive a time synchronization signal along the electrical cable 100.

In some examples, the first sensor data and the second sensor data are indicative of at least one of a fault direction, fault measurements, fault alerts, a fault voltage, a transient voltage event, electrical-asset-health alerts, a partial-discharge event quantity, a partial-discharge magnitude, a partial-discharge waveform, a partial-discharge calibration, partial-discharge statistical information, partial-discharge-based alerts, incipient faults, cable diagnostic signals, a voltage presence, a voltage waveform, waveform-based alerts, a relative voltage phase information, a voltage magnitude and voltage phase, an impedance, power-quality measurements, power-quality diagnostics, a power factor, a frequency domain reflectometry signal characteristic, a cable location signal, a defect location signal, load measurements, an amount of reactive power or active power, an estimated distance between the at least one secondary node and a detected fault, a detected partial-discharge event, or a waveform anomaly, relative time references or absolute time references, an identifier for the at least one secondary node, actuation and control signals, or timing or synchronization signals. In some examples, one or both of the first and second monitoring nodes 1222 are configured to harvest power from the electrical powerline, e.g., cable 100A.

In some examples, monitoring node 1222, e.g., via a sensor and/or transceiver of monitoring node 1222, is configured to output a signal to the electrical cable 100A and a locator is configured to locate at least one of a presence of the signal along the electrical cable 100A, an absence of the signal along the electrical cable 100A, or a change of the signal along the electrical cable 100A. For example, an operator may cause monitoring node 1222 to inject a signal to electrical cable 100A and described above with reference to FIG. 15, and the operator may use locating device 1502 to locate a defect, or the cable 100A itself, at a particular position and/or site on a surface of the ground, e.g., above-ground.

The techniques of this disclosure may further include determining, based on the first sensor data, a condition of the electric powerline (e.g., including any of at least electrical-power cables 100, power networks 200A, 200B, cable 202, cable 600), a condition of the powerline (1606). For example, central computing system 220 may receive the first sensor data and determine, based on the first sensor data, a health of a component of the electric powerline, a failure condition of a device coupled to the power line, a pre-failure condition of a device coupled to the power line, one or more environmental conditions at a monitoring node, a state or operability of an electrical grid comprising the electric powerline, a presence of a defect in the electric powerline, or a location of a defect in the electric powerline. For example, central computing system may determine a failure condition or a pre-failure condition of a device couple to the power line such as a switch, a transformer, a substation bus, a circuit breaker, an automatic circuit reclosers, a sectionalizer, and/or any other cable accessories.

The techniques may further include increasing, based on the second sensor data, an accuracy of the determination of the condition (1608). For example, central computing system 220 may receive the second sensor data and determine, based on the second sensor data, of the health of the component of the electric powerline, the one or more environmental conditions at the node, the state or operability of the electrical grid comprising the electric powerline, the presence of the defect in the electric powerline, or the location of the defect in the electric powerline.

In examples described herein, a monitoring node, e.g., monitoring node 1222, and/or central computing system 220 may be configured to make determinations and/or improve the accuracy of determinations based on a plurality of sensor data, e.g., first sensor data and second sensor data. For example, monitoring node 1222 may acquire voltage and/or current sensor data indicative of a fault. The monitoring node 1222, or a different monitoring node 1222 at a different location, may initiate a reflectometry scan based a fault detection based on the voltage and/or current sensor data, e.g., automatically or manually, and acquire reflectometry sensor data. Monitoring device 1222 and/or central computing system 220 may estimate or determine the fault location based on both the reflectometry sensor data and the voltage and/or current sensor data. In some examples, determining the fault location based at least partially on at the reflectometry sensor data is beneficial in cases where a short circuit and/or fault is transient (e.g., goes away and/or is intermittent) or if the power to the powerline is cut. In another example, monitoring node 1222 may initiate the reflectometry scan while the network is still in an electrical fault short condition, and monitoring device 1222 and/or central computing system 220 may estimate or determine the fault location based on both the reflectometry sensor data and the voltage and/or current sensor data. For example, the electrical power network may experience a short circuit, which may remain for a relatively short duration (e.g., a few cycles), until the power is interrupted (e.g., by a device such as a breaker). Within the short duration before the power is interrupted, monitoring node 1222 may initiate a reflectometry scan while the electrical power network is still experiencing the short circuit in order to estimate or determine the location of the short circuit. In another example, the electrical power network may experience a transient event (e.g., a self-clearing fault) such that the event is short enough, or low enough amplitude/magnitude, that the power is not interrupted (e.g., by a device such as a breaker). Monitoring node 1222 may initiate a reflectometry scan during the active period of the transient event, in order to estimate or determine the location of the transient event.

In another example, monitoring node 1222 may acquire reflectometry sensor data and determine (or central computing system 220 may determine) a point of high reflection in the network at some location away from monitoring node 1222 based on the reflectometry sensor data. A distance to the location may be known, or estimated, or the location of the reflection point may be physically known. Monitoring device 1222 may also acquire PD sensor data detected from a source that is between monitoring device 1222 and the point of high reflection, and the same monitoring device 1222 may also acquire PD sensor data (e.g., second PD sensor data) of the reflection of the PD signal reflected from the point of high reflection. Monitoring device 1222 may also acquire sensor data of subsequent reflections (e.g., reflectometry, PD, etc.), Monitoring device 1222 and/or central computing system 220 may estimate, pinpoint, or determine the fault location based on the reflected signals, e.g., any of all of one or more reflectometry sensor data. PD sensor data, and reflected PD sensor data. For example, monitoring device 1222 and/or central computing system 220 may pinpoint the PD location based on correlating FDR and PD signals, e.g., a time difference between direct (PD) and reflected (FDR) pulses may be twice the distance between the source of the PD and the remote reflector, divided by the propagation velocity, thus pinpointing the location. In another example, monitoring device 1222 and/or central computing system 220 may determine a temperature and/or a temperature change of the powerline based on FDR data and/or signals, and may correlate the temperature and/or temperature changes to PD signals, pulses, levels, and/or pulse shape. For example, monitoring device 1222 and/or central computing system 220 may determine a correlation between PD severity (frequency of PD events, PD amplitude/magnitude) and a portion of the electrical power network (e.g., a cable segment) and the temperature of the portion of the electrical power network (e.g., as determined via FDR), and monitoring device 1222 and/or central computing system 220 may determine a characteristic (e.g., a type of defect, a severity of a defect, or the like) based on the correlation and/or its behavior over time. In some examples, monitoring device 1222 and/or central computing system 220 may determine a characteristic based on additional information, signals, or data such as temperature the local environment (e.g., near a portion of the electrical power network), other local environmental conditions (e.g., a flooding, above-ground fire, and the like), or powerline current.

In another example, monitoring device 1222 and/or central computing system 220 may determine a temperature and/or a temperature change of the powerline based on FDR data and/or signals, and may correlate the temperature and/or temperature changes to powerline current of at least a portion of the electrical power network (e.g., a section of powerline cable). For example, monitoring device 1222 and/or central computing system 220 may determine a correlation between powerline current level and the temperature of the portion of the electrical power network (e.g., as determined via FDR), and monitoring device 1222 and/or central computing system 220 may determine a characteristic (e.g., a type of defect, a severity of a defect, or the like) based on the correlation and/or its behavior over time. In some examples, monitoring device 1222 and/or central computing system 220 may determine a characteristic based on additional information, signals, or data such as temperature the local environment (e.g., near a portion of the electrical power network), or other local environmental conditions (e.g., a flooding, above-ground fire, and the like).

In another example, monitoring node 1222 may acquire reflectometer sensor data (e.g., FDR, TDR, or the like). Monitoring device 1222 and/or central computing system 220 may then characterize the cable propagation characteristics, e.g., attenuation of signals over a length of the cable 100A, based on reflectometer sensor data. In some examples, monitoring device 1222 and/or central computing system 220 may estimate a distance to a remote PD source based on the reflectometer sensor data combined with other sensor data and/or other information, e.g., in combination with dispersion analysis. For example, monitoring device 1222 and/or central computing system 220 may filter a PD pulse shape based on frequency and distance dependent properties of the cable, and monitoring device 1222 and/or central computing system 220 may measure and determine the frequency and distance dependent properties of the cable based on FDR. Monitoring device 1222 and/or central computing system 220 may determine an approximate distance to an event (e.g., fault, source of PD) based on analysis of PD pulse shape, and monitoring device 1222 and/or central computing system 220 may calibrate PD pulse intensity by correlating PD pulse shape (or bandwidth) to the cable attenuation characteristics.

In another example, monitoring node 1222 may acquire PD sensor data from a remote source. At a later time, monitoring node 1222 may acquire voltage and/or current sensor data indicative of voltage and/or current waveforms indicative of a subcycle transient from the same region of cable. Monitoring device 1222 and/or central computing system 220 may then determine and assign a severity and risk index to that specific section of the cable system based on both the acquired sensor data indicating an increase in activity from partial discharges and/or transients, e.g., with a reduced likelihood of false positive indication of defect. Monitoring device 1222 and/or central computing system 220 may also determine a location of the defect with an increased accuracy based on both the PD sensor data and the voltage and/or current waveforms indicative of a subcycle transient, e.g., both sensor data types provide an estimate that may be checked and/or revised based on the other method, or one sensor data type is more accurate than the other and monitoring device 1222 and/or computing device 220 determine the location based on the more accurate sensor data type.

In another example, monitoring node 1222 may acquire reflectometer sensor data (e.g., FDR, TDR, or the like), to map structural changes in the cable system, e.g., joints, terminations, or the like. Monitoring node 1222 and/or central computing system 220 may estimate a distance to each of the structural changes based on the reflectometry sensor data. Monitoring node 1222 may also acquire PD sensor data and/or voltage and/or current sensor data indicative of transient electrical events, and may estimate a location of the PD and/or events. A structural change in the cable may have an increased likelihood of being the source of a defect, failure, and/or transient electrical event. Monitoring node 1222 and/or central computing system 220 may use the reflectometer sensor data, PD sensor data, and/or voltage and/or current sensor data in combination to provide likely defect, failure, and/or event sources and locations and to determine which reflectometer-detected structure is the most likely defective one. The defect at the structural change location can then be tracked and later found and repaired.

In another example, monitoring node 1222 may acquire sensor data indicative of a cable system defect (e.g., pre-fault or after a fault) and determine and/or estimate a location of the defect based on reflectometer sensor data, PD sensor data, or any other suitable sensor data. Monitoring device 1222 may then send and/or inject a signal along the cable 100A to determine the cable location, e.g., in combination with locating device 1502. The combination of location from the reflectometer sensor data, PD sensor data, and locating device 1502 markings may be used to determine a defect site to find and repair the defect. In some examples, a plurality of monitoring nodes 1222 may send and/or inject intentional communication signals between them through the voltage connection, e.g., cable 100A, and may use the communication signals for synchronization of the monitoring nodes 1222. In some examples, the monitoring devices may use the communication signals to characterize and diagnose cable 100A between monitoring, nodes 1222 locations, e.g., length, attenuation at frequency, impedance, and the like.

In some examples, a plurality of monitoring nodes 1222 at different locations may acquire PD sensor data, e.g., a first PD sensor data acquired by a first monitoring node 1222 and a second PD sensor data acquired by a second monitoring node 1222. Monitoring node 1222 and/or central computing system 220 may determine a PD source and/or its location based on the first or second PD sensor data, and confirm and/or improve the accuracy of the determination based on the other of the second or first PD sensor data. For example, central computing system 220 may, based on both the first and second PD sensor data, determine the source and/or its location using PD signal magnitude, phase resolved behavior, repetition rate, quiet periods over time, or other means, and/or may overlay of location estimates based on first PD sensor data and second PD sensor data, e.g., to improve a location estimate (e.g., two vs one estimate).

In some examples, a plurality of monitoring nodes 1222 at different locations may acquire reflectometry sensor data, and central computing system 220 may determine and/or estimate a location of a structural anomaly (a defect) or intentional structural change in the cable system (branch, joint, termination) based on the reflectometer sensor data. Central computing system 220 may overlay of the plurality of location estimates to provide a more accurate location estimate,

In some examples, a plurality of monitoring nodes 1222 at different locations may send and/or inject intentional communication signals between monitoring nodes 1222, e.g., and use the intentional communication signals to time synchronize with each other. For example, after synchronization, central computing system 220 may identify the arrival of individual or group PD signals at a plurality of monitoring nodes 1222 as coming from the same PD source.

In some examples, a plurality of monitoring nodes 1222 at different locations may be synchronized via some other means, e.g., a GPS system. Monitoring nodes 1222 and/or central computing system 220 may identify a PD source based on the arrival of individual and/or group PD signals at the plurality of monitoring nodes 1222 and based on, e.g., a PD signal magnitude, phase resolved behavior, repetition rate, quiet periods over time, or the like. Monitoring nodes 1222 and/or central computing system 220 may determine and/or estimate a location of the PD source based on a comparison of the arrival times of the PD signal(s) between two or more monitoring nodes 1222.

In the present detailed description of the preferred embodiments, reference is made to the accompanying drawings, which illustrate specific embodiments in which the invention may be practiced. The illustrated embodiments are not intended to be exhaustive of all embodiments according to the invention. It is to be understood that other embodiments may be utilized, and structural or logical changes may be made without departing from the scope of the present invention. The following detailed description, therefore, is not to be taken in a limiting sense, and the scope of the present invention is defined by the appended claims.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “proximate,” “distal,” “lower,” “upper,” “beneath,” “below,” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as “below” or “beneath” other elements would then be above or on top of those other elements

The techniques of this disclosure may be implemented in a wide variety of computer devices, such as servers, laptop computers, desktop computers, notebook computers, tablet computers, hand-held computers, smart phones, and the like. Any components, modules or units have been described to emphasize functional aspects and do not necessarily require realization by different hardware units. The techniques described herein may also be implemented in hardware, software, firmware, or any combination thereof. Any features described as modules, units or components may be implemented together in an integrated logic device or separately as discrete but interoperable logic devices. In some cases, various features may be implemented as an integrated circuit device, such as an integrated circuit chip or chipset. Additionally, although a number of distinct modules have been described throughout this description, many of which perform unique functions, all the functions of all of the modules may be combined into a single module, or even split into further additional modules. The modules described herein are only exemplary and have been described as such for better ease of understanding.

If implemented in software, the techniques may be realized at least in part by a computer-readable medium comprising instructions that, when executed in a processor, performs one or more of the methods described above. The computer-readable medium may comprise a tangible computer-readable storage medium and may form part of a computer program product, which may include packaging materials. The computer-readable storage medium may comprise random access memory (RAM) such as synchronous dynamic random-access memory (SDRAM), read-only memory (ROM), non-volatile random-access memory (NVRAM), electrically erasable programmable read-only memory (EEPROM), FLASH memory, magnetic or optical data storage media, and the like. The computer-readable storage medium may also comprise a non-volatile storage device, such as a hard-disk, magnetic tape, a compact disk (CD), digital versatile disk (DVD), Blu-ray disk, holographic data storage media, or other non-volatile storage device.

The term “processor,” as used herein may refer to any of the foregoing structure or any other structure suitable for implementation of the techniques described herein. In addition, in some aspects, the functionality described herein may be provided within dedicated software modules or hardware modules configured for performing the techniques of this disclosure. Even if implemented in software, the techniques may use hardware such as a processor to execute the software, and a memory to store the software. In any such cases, the computers described herein may define a specific machine that is capable of executing the specific functions described herein. Also, the techniques could be fully implemented in one or more circuits or logic elements, which could also be considered a processor.

In one or more examples, the functions described may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor”, as used may refer to any of the foregoing structure or any other structure suitable for implementation of the techniques described. In addition, in some aspects, the functionality described may be provided within dedicated hardware and/or software modules. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

It is to be recognized that depending on the example, certain acts or events of any of the methods described herein can be performed in a different sequence, may be added, merged, or left out altogether (e.g., not all described acts or events are necessary for the practice of the method). Moreover, in certain examples, acts or events may be performed concurrently, e.g., through multi-threaded processing, interrupt processing, or multiple processors, rather than sequentially.

In some examples, a computer-readable storage medium includes a non-transitory medium. The term “non-transitory” indicates, in some examples, that the storage medium is not embodied in a carrier wave or a propagated signal. In certain examples, a non-transitory storage medium stores data that can, over time, change (e.g., in RAM or cache).

This disclosure includes the following examples:

Example 1: A system configured to monitor one or more conditions of an electric powerline comprising one or more electrical cables, the system including: a node operatively coupled to an electrical cable of the one or more electrical cables and communicatively coupled to a central computing system, wherein the node comprises: a sensor configured to acquire a first sensor data and to acquire a second sensor data different from the first sensor data, wherein the node is configured to deliver the first sensor data and the second sensor data to the central computing system.

Example 2: The system of example 1, wherein the first sensor data comprises a first sensor data type and the second sensor data comprises a second sensor data type different from the first sensor data type, wherein the first and second sensor data types comprise at least one of a frequency domain reflectometry, a time domain reflectometry, a partial discharge, a voltage, a current, or a temperature.

Example 3: The system of any one of examples 1 or 2, wherein the first sensor data and the second sensor data comprises the same data type, wherein the first sensor data and the second sensor data are acquired at different times.

Example 4: The system of any one of examples 1 through 3, wherein the node is a first node coupled to the electrical cable at a first location, wherein the sensor is a first sensor, wherein the system further comprises: a second node operatively coupled to the electrical cable of the one or more electrical cables at a second location, wherein the second node comprises: a second sensor configured to acquire at least one of the first sensor data or the second sensor data.

Example 5: The system of example 4, wherein first location and the second location comprise at least one of a termination point of respective cables of the one or more electrical cables, a branch point of respective cables of the one or more electrical cables, a respective medium-voltage cable of the one or more electrical cables, or a cable accessory of a respective cable of the one or more electrical cables.

Example 6: The system of example 5, wherein the first node and the second node are configured to send and receive a time synchronization signal along the electrical cable.

Example 7: The system of any one of examples 1 through 6, wherein the first sensor data and the second sensor data indicates at least one of: a fault direction; fault measurements; fault alerts; a fault voltage; a transient voltage event; electrical-asset-health alerts; a partial-discharge event quantity; a partial-discharge magnitude; a partial-discharge waveform; a partial-discharge calibration; partial-discharge statistical information; partial-discharge-based alerts; incipient faults; cable diagnostic signals; a voltage presence; a voltage waveform; waveform-based alerts; a relative voltage phase information; a voltage magnitude and voltage phase; an impedance; power-quality measurements; power-quality diagnostics; a power factor; a frequency domain reflectometry signal characteristic; a cable location signal; a defect location signal; load measurements; an amount of reactive power or active power; an estimated distance between the at least one secondary node and a detected fault, a detected partial-discharge event, or a waveform anomaly; relative time references or absolute time references; an identifier for the at least one secondary node; actuation and control signals; or timing or synchronization signals.

Example 8: The system of any one of examples 1 through 7, wherein the system includes the central computing system and wherein the central computing system is configured to determine, based on the first sensor data, at least one of a health of a component of the electric powerline, one or more environmental conditions at the node, a state or operability of an electrical grid comprising the electric powerline, a presence of a defect in the electric powerline, or a location of a defect in the electric powerline, wherein the central computing system is configured to increase an accuracy of the determination, based on the second sensor data, of the at least one of the health of a component of the electric powerline, the one or more environmental conditions at the node, the state or operability of the electrical grid comprising the electric powerline, the presence of the defect in the electric powerline, or the location of the defect in the electric powerline.

Example 9: The system of any one of examples 1 through 8, wherein the node is configured to harvest power from the electrical cable.

Example 10: The system of any one of examples 1 through 9, wherein the sensor is configured to output a signal to the electrical cable, wherein a locator is configured to locate at least one of a presence of the signal along the electrical cable, an absence of the signal along the electrical cable, or a change of the signal along the electrical cable.

Example 11: A node including: a sensor configured to acquire a first sensor data and to acquire a second sensor data different from the first sensor data, wherein the node operatively coupled to an electrical cable of an electric powerline and communicatively coupled to a central computing system, wherein the node is configured to deliver the first sensor data and the second sensor data to the central computing system.

Example 12: The node of example 11, wherein the first sensor data comprises a first sensor data type and the second sensor data comprises a second sensor data type different from the first sensor data type, wherein the first and second sensor data types comprise at least one of a frequency domain reflectometry, a time domain reflectometry, a partial discharge, a voltage, a current, or a temperature.

Example 13: The node of any one of examples 11 or 12, wherein the first sensor data and the second sensor data comprises the same data type, wherein the first sensor data and the second sensor data are acquired at different times.

Example 14: The node of any one of examples 11 through 13, wherein the node is a first node coupled to the electrical cable at a first location, wherein the sensor is a first sensor, wherein the first node is configured to send and receive a time synchronization signal along the electrical cable between the first node and a second node operatively coupled to the electrical cable of the one or more electrical cables at a second location, wherein the second node is configured to send and receive the time synchronization signal along the electrical cable between the first node and a second node, wherein the second node comprises a second sensor configured to acquire at least one of the first sensor data or the second sensor data.

Example 15: The system of example 14, wherein first location and the second location comprise at least one of a termination point of respective cables of the one or more electrical cables, a branch point of respective cables of the one or more electrical cables, a respective medium-voltage cable of the one or more electrical cables, or a cable accessory of a respective cable of the one or more electrical cables.

Example 16: The node of any one of examples 11 through 15, wherein the first sensor data and the second sensor data indicates at least one of: a fault direction; fault measurements; fault alerts; a fault voltage; a transient voltage event; electrical-asset-health alerts; a partial-discharge event quantity; a partial-discharge magnitude; a partial-discharge waveform; a partial-discharge calibration; partial-discharge statistical information; partial-discharge-based alerts; incipient faults; cable diagnostic signals; a voltage presence; a voltage waveform; waveform-based alerts; a relative voltage phase information; a voltage magnitude and voltage phase; an impedance; power-quality measurements; power-quality diagnostics; a power factor; a frequency domain reflectometry signal characteristic; a cable location signal; a defect location signal; load measurements; an amount of reactive power or active power; an estimated distance between the at least one secondary node and a detected fault, a detected partial-discharge event, or a waveform anomaly; relative time references or absolute time references; an identifier for the at least one secondary node; actuation and control signals; or timing or synchronization signals.

Example 17: The node of any one of examples 1 through 16, wherein the node is operatively coupled to a central computing system, wherein the central computing system is configured to determine, based on the first sensor data, at least one of a health of a component of the electric powerline, one or more environmental conditions at the node, a state or operability of an electrical grid comprising the electric powerline, a presence of a defect in the electric powerline, or a location of a defect in the electric powerline, wherein the central computing system is configured to increase an accuracy of the determination, based on the second sensor data, of the at least one of the health of a component of the electric powerline, the one or more environmental conditions at the node, the state or operability of the electrical grid comprising the electric powerline, the presence of the defect in the electric powerline, or the location of the defect in the electric powerline.

Example 18: The node of any one of examples 11 through 17, wherein the node is configured to harvest power from the electrical cable.

Example 19: The node of any one of examples 11 through 18, wherein the sensor is configured to output a signal to the electrical cable, wherein a locator is configured to locate at least one of a presence of the signal along the electrical cable, an absence of the signal along the electrical cable, or a change of the signal along the electrical cable.

Example 20: A method including: receiving, from a node operatively coupled to an electrical cable of an electric powerline, a first sensor data; receiving, from the node, a second sensor data different from the first sensor data; determining, based on the first sensor data, at least one of a health of a component of the electric powerline, a failure condition of a device coupled to the power line, a pre-failure condition of a device coupled to the power line, one or more environmental conditions at the node, a state or operability of an electrical grid comprising the electric powerline, a presence of a defect in the electric powerline, or a location of a defect in the electric powerline; and increasing, based on the second sensor data, an accuracy of the determination.

Various examples have been described. These and other examples are within the scope of the following claims.

What is claimed is:

1. A system configured to monitor one or more conditions of an electric powerline comprising one or more electrical cables, the system comprising:
a node operatively coupled to an electrical cable of the one or more electrical cables and communicatively coupled to a central computing system, wherein the node comprises:
a sensor configured to acquire a first sensor data and to acquire a second sensor data different from the first sensor data,
wherein the node is configured to deliver the first sensor data and the second sensor data to the central computing system.

2. The system of claim 1, wherein the first sensor data comprises a first sensor data type and the second sensor data comprises a second sensor data type different from the first sensor data type, wherein the first and second sensor data types comprise at least one of a frequency domain reflectometry, a time domain reflectometry, a partial discharge, a voltage, a current, or a temperature.

3. The system of claim 1, wherein the first sensor data and the second sensor data comprises the same data type, wherein the first sensor data and the second sensor data are acquired at different times.

4. The system of claim 1, wherein the node is a first node coupled to the electrical cable at a first location, wherein the sensor is a first sensor, wherein the system further comprises:
a second node operatively coupled to the electrical cable of the one or more electrical cables at a second location, wherein the second node comprises;
a second sensor configured to acquire at least one of the first sensor data or the second sensor data.

5. The system of claim 4, wherein first location and the second location comprise at least one of a termination point of respective cables of the one or more electrical cables, a branch point of respective cables of the one or more electrical cables, a respective medium-voltage cable of the one or more electrical cables, or a cable accessory of a respective cable of the one or more electrical cables.

6. The system of claim 5, wherein the first node and the second node are configured to send and receive a time synchronization signal along the electrical cable.

7. The system of claim 1, wherein the first sensor data and the second sensor data indicates at least one of:
a fault direction;
fault measurements;
fault alerts;
a fault voltage;
a transient voltage event;
electrical-asset-health alerts;
a partial-discharge event quantity;
a partial-discharge magnitude;
a partial-discharge waveform;
a partial-discharge calibration;
partial-discharge statistical information;
partial-discharge-based alerts;
incipient faults;
cable diagnostic signals;
a voltage presence;
a voltage waveform;
waveform-based alerts;
a relative voltage phase information;
a voltage magnitude and voltage phase;
an impedance;
power-quality measurements;
power-quality diagnostics;
a power factor;
a frequency domain reflectometry signal characteristic;
a cable location signal;
a defect location signal;
load measurements;
an amount of reactive power or active power;
an estimated distance between the at least one secondary node and a detected fault, a detected partial-discharge event, or a waveform anomaly;
relative time references or absolute time references;
an identifier for the at least one secondary node;
actuation and control signals; or
timing or synchronization signals.

8. The system of claim 1, wherein the system includes the central computing system and wherein the central computing system is configured to determine, based on the first sensor data, at least one of a health of a component of the electric powerline, one or more environmental conditions at the node, a state or operability of an electrical grid comprising the electric powerline, a presence of a defect in the electric powerline, or a location of a defect in the electric powerline,
wherein the central computing system is configured to increase an accuracy of the determination, based on the second sensor data, of the at least one of the health of a component of the electric powerline, the one or more environmental conditions at the node, the state or operability of the electrical grid comprising the electric powerline, the presence of the defect in the electric powerline, or the location of the defect in the electric powerline.

9. The system of claim 1, wherein the node is configured to harvest power from the electrical cable.

10. The system of claim 1, wherein the sensor is configured to output a signal to the electrical cable, wherein a locator is configured to locate at least one of a presence of the signal along the electrical cable, an absence of the signal along the electrical cable, or a change of the signal along the electrical cable.

11. A node comprising:
a sensor configured to acquire a first sensor data and to acquire a second sensor data different from the first sensor data,
wherein the node operatively coupled to an electrical cable of an electric powerline and communicatively coupled to a central computing system,
wherein the node is configured to deliver the first sensor data and the second sensor data to the central computing system.

12. The node of claim 11, wherein the first sensor data comprises a first sensor data type and the second sensor data comprises a second sensor data type different from the first sensor data type, wherein the first and second sensor data types comprise at least one of a frequency domain reflectometry, a time domain reflectometry, a partial discharge, a voltage, a current, or a temperature.

13. The node of claim 11, wherein the first sensor data and the second sensor data comprises the same data type, wherein the first sensor data and the second sensor data are acquired at different times.

14. The node of claim 11, wherein the node is a first node coupled to the electrical cable at a first location, wherein the sensor is a first sensor,
wherein the first node is configured to send and receive a time synchronization signal along the electrical cable between the first node and a second node operatively coupled to the electrical cable of the one or more electrical cables at a second location,
wherein the second node is configured to send and receive the time synchronization signal along the electrical cable between the first node and a second node,
wherein the second node comprises a second sensor configured to acquire at least one of the first sensor data or the second sensor data.

15. The system of claim 14, wherein first location and the second location comprise at least one of a termination point of respective cables of the one or more electrical cables, a branch point of respective cables of the one or more electrical cables, a respective medium-voltage cable of the one or more electrical cables, or a cable accessory of a respective cable of the one or more electrical cables.

16. The node of claim 11, wherein the first sensor data and the second sensor data indicates at least one of:
a fault direction;
fault measurements;
fault alerts;
a fault voltage;
a transient voltage event;
electrical-asset-health alerts;
a partial-discharge event quantity;
a partial-discharge magnitude;
a partial-discharge waveform;
a partial-discharge calibration;
partial-discharge statistical information;
partial-discharge-based alerts;
incipient faults;
cable diagnostic signals;
a voltage presence;
a voltage waveform;
waveform-based alerts;
a relative voltage phase information;
a voltage magnitude and voltage phase;
an impedance;
power-quality measurements;
power-quality diagnostics;
a power factor;
a frequency domain reflectometry signal characteristic;
a cable location signal;
a defect location signal;
load measurements;
an amount of reactive power or active power;
an estimated distance between the at least one secondary node and a detected fault, a detected partial-discharge event, or a waveform anomaly;
relative time references or absolute time references;
an identifier for the at least one secondary node;
actuation and control signals; or
timing or synchronization signals.

17. The node of claim 1, wherein the node is operatively coupled to a central computing system, wherein the central computing system is configured to determine, based on the first sensor data, at least one of a health of a component of the electric powerline, one or more environmental conditions at the node, a state or operability of an electrical grid comprising the electric powerline, a presence of a defect in the electric powerline, or a location of a defect in the electric powerline,
wherein the central computing system is configured to increase an accuracy of the determination, based on the second sensor data, of the at least one of the health of a component of the electric powerline, the one or more environmental conditions at the node, the state or operability of the electrical grid comprising the electric powerline, the presence of the defect in the electric powerline, or the location of the defect in the electric powerline.

18. The node of claim 11, wherein the node is configured to harvest power from the electrical cable.

19. The node of claim 11, wherein the sensor is configured to output a signal to the electrical cable, wherein a locator is configured to locate at least one of a presence of the signal along the electrical cable, an absence of the signal along the electrical cable, or a change of the signal along the electrical cable.

20. A method comprising:
receiving, from a node operatively coupled to an electrical cable of an electric powerline, a first sensor data;
receiving, from the node, a second sensor data different from the first sensor data;
determining, based on the first sensor data, at least one of a health of a component of the electric powerline, a failure condition of a device coupled to the power line, a pre-failure condition of a device coupled to the power line, one or more environmental conditions at the node, a state or operability of an electrical grid comprising the electric powerline, a presence of a defect in the electric powerline, or a location of a defect in the electric powerline; and
increasing, based on the second sensor data, an accuracy of the determination.
